(19) United States
(12) Patent Application Publication
(10) Pub. No.: US 2026/0082536 A1
(43) Pub. Date: Mar. 19, 2026

(54) MEMORY DEVICE

(71) Applicant: Kioxia Corporation, Tokyo (JP)

(72) Inventors: Takafumi MASUDA, Yokkaichi Mie (JP); Nobuyoshi SAITO, Tokyo (JP); Mutsumi OKAJIMA, Yokkaichi Mie (JP)

(73) Assignee: Kioxia Corporation, Tokyo (JP)

(21) Appl. No.: 19/076,741

(22) Filed: Mar. 11, 2025

(30) Foreign Application Priority Data
Sep. 19, 2024 (JP) 2024-162681

(51) Int. Cl. H10B 12/00

(52) U.S. Cl. CPC H10B 12/00

(57) ABSTRACT

According to one embodiment, a memory device includes a substrate, first and second conductive members, memory cells, and a shield electrode. Each of the first and second conductive members is provided to extend in a first direction. The first and second conductive members are arranged in a second direction. The memory cells are arranged in the first direction. Each of the memory cells includes first and second transistors arranged in the second direction. The first transistor includes a channel region electrically connected to the first conductive member. The second transistor includes a channel region connected to the second conductive member and a gate electrode connected to the channel region of the first transistor. The shield electrode is connected to the second conductive member between two memory cells adjacent in the first direction. The shield electrode overlaps the gate electrode of the second transistor in the first direction.

### CROSS-REFERENCE TO RELATED APPLICATIONS

This application is based upon and claims the benefit of priority from Japanese Patent Application No. 2024-162681, filed Sep. 19, 2024, the entire contents of which are incorporated herein by reference.

### FIELD

Embodiments described herein relate generally to a memory device

### BACKGROUND

Dynamic random access memories (DRAM) including three-dimensionally stacked memory cells are known.

### BRIEF DESCRIPTION OF DRAWINGS

FIG. 1 is a block diagram illustrating an example of a configuration of a memory system including a memory device according to a first embodiment.

FIG. 2 is a perspective view illustrating an example of a structure of the memory device according to the first embodiment.

FIG. 3 is a circuit diagram illustrating an example of a circuit configuration of a memory cell included in the memory device according to the first embodiment.

FIG. 4 is a cross-sectional view illustrating an example of a structure of a memory cell array included in the memory device according to the first embodiment.

FIG. 5 is a cross-sectional view taken along line V-V in FIG. 4, illustrating an example of a structure of the memory cell array included in the memory device according to the first embodiment.

FIG. 6 is a cross-sectional view taken along line VI-VI in FIG. 4, illustrating an example of a structure of the memory cell array included in the memory device according to the first embodiment.

FIGS. 7, 8, and 9 are cross-sectional views illustrating an example of a structure in steps for manufacturing the memory device according to the first embodiment.

FIG. 10 is a cross-sectional view taken along line X-X in FIG. 9, illustrating an example of a structure in a step for manufacturing the memory device according to the first embodiment.

FIG. 11 is a cross-sectional view illustrating an example of a structure in a step for manufacturing the memory device according to the first embodiment.

FIG. 12 is a cross-sectional view taken along line XII-XII in FIG. 11, illustrating an example of a structure in a step for manufacturing the memory device according to the first embodiment.

FIGS. 13 and 14 are cross-sectional views illustrating an example of a structure in steps for manufacturing the memory device according to the first embodiment.

FIG. 15 is a cross-sectional view taken along line XV-XV in FIG. 14, illustrating an example of a structure in a step for manufacturing the memory device according to the first embodiment.

FIGS. 16, 17, 18, 19, 20, 21, 22, 23, and 24 are cross-sectional views illustrating an example of a structure in steps for manufacturing the memory device according to the first embodiment.

FIG. 25 is a circuit diagram illustrating an example of a circuit configuration of a memory cell included in a memory device according to a comparative example.

FIG. 26 is a cross-sectional view illustrating an example of a structure of a memory cell array included in the memory device according to the comparative example.

FIG. 27 is a cross-sectional view illustrating an example of a structure of a memory cell array included in a memory device according to a second embodiment.

FIG. 28 is a cross-sectional view taken along line XXVIII-XXVIII in FIG. 27, illustrating an example of a structure of the memory cell array included in the memory device according to the second embodiment.

FIG. 29 is a cross-sectional view taken along line XXIX-XXIX in FIG. 27, illustrating an example of a structure of the memory cell array included in the memory device according to the second embodiment.

FIG. 30 is a cross-sectional view illustrating an example of a structure in a step for manufacturing the memory device according to the second embodiment.

FIG. 31 is a cross-sectional view taken along line XXXI-XXXI in FIG. 30, illustrating an example of a structure in a step for manufacturing the memory device according to the second embodiment.

FIG. 32 is a cross-sectional view illustrating an example of a structure in a step for manufacturing the memory device according to the second embodiment.

FIG. 33 is a cross-sectional view illustrating an example of a structure in a step for manufacturing the memory device according to the second embodiment.

FIG. 34 is a cross-sectional view taken along line XXXIV-XXXIV in FIG. 33, illustrating an example of a structure in a step for manufacturing the memory device according to the second embodiment.

FIG. 35 is a cross-sectional view illustrating an example of a structure in a step for manufacturing the memory device according to the second embodiment.

FIG. 36 is a cross-sectional view taken along line XXXVI-XXXVI in FIG. 35, illustrating an example of a structure in a step for manufacturing the memory device according to the second embodiment.

FIG. 37 is a cross-sectional view illustrating an example of a structure in a step for manufacturing the memory device according to the second embodiment.

FIG. 38 is a cross-sectional view illustrating an example of a structure in a step for manufacturing the memory device according to the second embodiment.

FIG. 39 is a cross-sectional view taken along line XXXIX-XXXIX in FIG. 38, illustrating an example of a structure in a step for manufacturing the memory device according to the second embodiment.

FIG. 40 is a cross-sectional view illustrating an example of a structure in a step for manufacturing the memory device according to the second embodiment.

FIG. 41 is a cross-sectional view taken along line XLI-XLI in FIG. 40, illustrating an example of a structure in a step for manufacturing the memory device according to the second embodiment.

FIG. 42 is a cross-sectional view illustrating an example of a structure of a memory cell array included in a memory device according to a third embodiment.

FIG. 43 is a cross-sectional view taken along line XLIII-XLIII in FIG. 42, illustrating an example of a structure of the memory cell array included in the memory device according to the third embodiment.

FIG. 44 is a cross-sectional view illustrating an example of a structure of the memory cell array included in the memory device according to the third embodiment, and a cross-sectional view taken along line XLIV-XLIV in FIG. 42.

FIGS. 45 and 46 are cross-sectional views illustrating an example of a structure in steps for manufacturing the memory device according to the third embodiment.

FIG. 47 is a cross-sectional view taken along line XLVII-XLVII in FIG. 46, illustrating an example of a structure in a step for manufacturing the memory device according to the third embodiment.

FIG. 48 is a cross-sectional view illustrating an example of a structure in a step for manufacturing the memory device according to the third embodiment.

FIG. 49 is a cross-sectional view taken along line XLIX-XLIX in FIG. 48, illustrating an example of a structure in a step for manufacturing the memory device according to the third embodiment.

FIGS. 50 and 51 are cross-sectional views illustrating an example of a structure in steps for manufacturing the memory device according to the third embodiment.

FIG. 52 is a cross-sectional view taken along line LII-LII in FIG. 50, illustrating an example of a structure in a step for manufacturing the memory device according to the third embodiment.

FIGS. 53 and 54 are cross-sectional views illustrating an example of a structure in steps for manufacturing the memory device according to the third embodiment.

FIG. 55 is a cross-sectional view taken along line LV-LV in FIG. 54, illustrating an example of a structure in a step for manufacturing the memory device according to the third embodiment.

FIG. 56 is a cross-sectional view illustrating an example of a structure in a step for manufacturing the memory device according to the third embodiment.

FIG. 57 is a cross-sectional view taken along line XVII-XVII in FIG. 56, illustrating an example of a structure in a step for manufacturing the memory device according to the third embodiment.

FIGS. 58, 59, 60, and 61 are cross-sectional views illustrating an example of a structure in steps for manufacturing the memory device according to the third embodiment.

FIG. 62 is a cross-sectional view taken along line LXII-LXII in FIG. 61, illustrating an example of a structure in a step for manufacturing the memory device according to the third embodiment.

FIGS. 63 and 64 are cross-sectional views illustrating an example of a structure of a memory cell array included in a memory device according to a modification of the third embodiment.

FIG. 65 is a perspective view illustrating an example of a structure of a memory device according to a fourth embodiment.

FIG. 66 is a circuit diagram illustrating an example of a circuit configuration of a memory cell included in the memory device according to the fourth embodiment.

FIG. 67 is a cross-sectional view illustrating an example of a structure of a memory cell array included in the memory device according to the fourth embodiment.

FIG. 68 is a cross-sectional view taken along line LXVIII-LXVIII in FIG. 67, illustrating an example of a structure of the memory cell array included in the memory device according to the fourth embodiment.

FIG. 69 is a cross-sectional view taken along line LXIX-LXIX in FIG. 67, illustrating an example of a structure of the memory cell array included in the memory device according to the fourth embodiment.

FIGS. 70, 71, 72, 73, 74, 75, 76, 77, 78, and 79 are cross-sectional views illustrating an example of a structure in steps for manufacturing the memory device according to the fourth embodiment.

### DETAILED DESCRIPTION

In general, according to one embodiment, a memory device includes a substrate, a first conductive member and a second conductive member, a plurality of memory cells, and a shield electrode. Each of the first conductive member and the second conductive member is provided to extend in a first direction intersecting a surface of the substrate. The first conductive member and the second conductive member are arranged in a second direction parallel to a surface of the substrate. The plurality of memory cells are arranged in the first direction. Each of the memory cells includes a first transistor and a second transistor arranged in the second direction. The first transistor includes a gate electrode and a channel region electrically connected to the first conductive member. The second transistor includes a channel region electrically connected to the second conductive member and a gate electrode electrically connected to the channel region of the first transistor. The shield electrode is electrically connected to the second conductive member between two memory cells adjacent in the first direction among the memory cells. The shield electrode is provided to overlap the gate electrode of the second transistor in the first direction.

Hereinafter, each embodiment will be described with reference to the drawings. Each embodiment exemplifies an apparatus and a method for embodying the technical idea of the invention. The drawings are schematic or conceptual. Dimensions, ratios, and the like of each drawing are not necessarily the same as actual ones. In the following description, components having substantially the same function and configuration are denoted by the same reference numerals.

In the present specification, a predetermined direction parallel to the upper surface of the substrate is referred to as an “X direction”. A direction parallel to the upper surface of the substrate and perpendicular to the X direction is referred to as a “Y direction”. A direction perpendicular to the upper surface of the substrate is referred to as a “Z direction”. A cross-section parallel to each of the X direction and the Z direction is referred to as an “XZ cross-section”. A cross-section parallel to each of the X direction and the Y direction is referred to as an “XY cross-section”. In addition, in the present specification, expressions such as “upper” and “lower” are based on the substrate. For example, a direction away from the substrate along the Z direction is referred to as “upper”, and a direction toward the substrate along the Z direction is referred to as “lower”. In addition, in a case where a certain configuration is referred to as a “lower surface” or a “lower end”, this means a surface or an end portion on the substrate side of this configuration. In a case where a certain configuration is referred to as an “upper surface” or an “upper end”, this means a surface or an end portion on the side opposite to the substrate of this configuration. In addition, a surface intersecting the X direction or the Y direction is referred to as a “side surface”.

### <1> FIRST EMBODIMENT

A memory device 100 according to a first embodiment is a type of dynamic random access memory (DRAM) including three-dimensionally stacked memory cells. In the following, details of the memory device 100 according to the first embodiment will be described.

### <1-1> Configuration

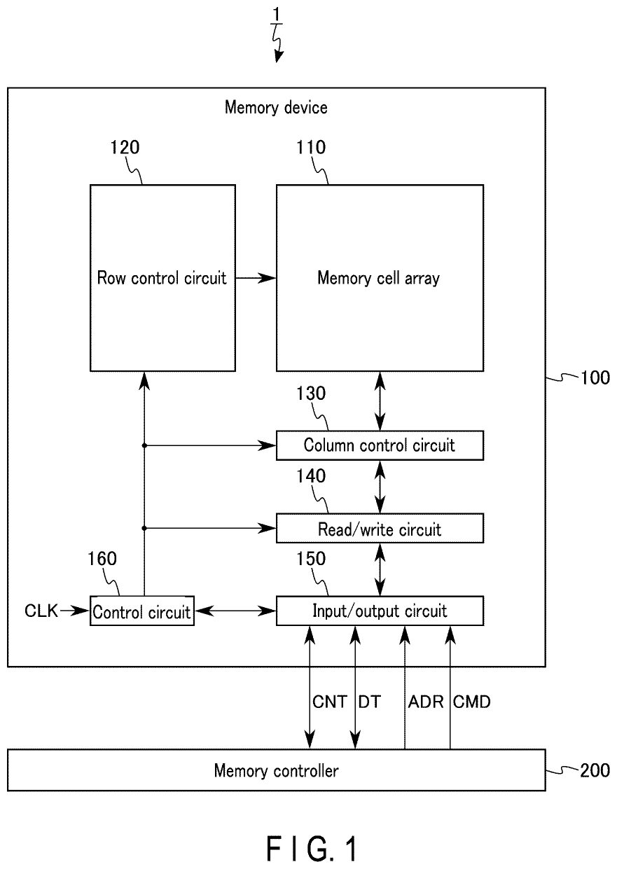

First, a configuration of a memory device 100 according to a first embodiment will be described with reference to FIGS. 1 to 6.

### <1-1-1> Configuration of Memory Device 100

FIG. 1 is a block diagram illustrating an example of a configuration of a memory system 1 including a memory device 100 according to a first embodiment. As illustrated in FIG. 1, the memory system 1 includes, for example, a memory device 100 and a memory controller 200. The memory device 100 is connected to the memory controller 200, and is configured to be able to read and write data based on a command of the memory controller 200. The memory device 100 receives, for example, the address ADR, the command CMD, the data DT, and the control signal CNT from the memory controller 200. The memory device 100 transmits the control signal CNT and the data DT to the memory controller 200. The memory device 100 includes, for example, a memory cell array 110, a row control circuit 120, a column control circuit 130, a read/write circuit 140, an input/output circuit 150, and a control circuit 160.

The memory cell array 110 is a circuit used to store data. Although not illustrated, the memory cell array 110 includes, for example, a plurality of memory cells MC, a plurality of word lines, and a plurality of bit lines. Each memory cell MC may store at least one bit of data. The plurality of word lines include a plurality of write word lines WWL and a plurality of read word lines RWL. The plurality of bit lines include a plurality of write bit lines WBL and a plurality of read bit lines RBL. Each memory cell MC is connected to a pair of write word line WWL and read word line RWL and a pair of write bit line WBL and read bit line RBL. For example, a row address is allocated to the pair of write word line WWL and read word line RWL. For example, a column address is allocated to the pair of write bit line WBL and read bit line RBL. Each memory cell MC can be specified by a row address and a column address.

The row control circuit 120 controls wiring lines (a write word line WWL and a read word line RWL) allocated in the row direction in the memory cell array 110. The row control circuit 120 selects a word line according to the address ADR (activation). In addition, the row control circuit 120 sets the non-selected word line to the non-selected state (deactivation). Then, the row control circuit 120 supplies a predetermined voltage to each of the selected word line and the non-selected word line. The row control circuit 120 includes, for example, a driver circuit to generate a voltage to be applied to the word line WL and an address decoder to decode the address ADR. The row control circuit 120 can select the pair of write word line WWL and read word line RWL based on the decoding result of the address ADR.

The column control circuit 130 controls the wiring lines (bit lines BL) allocated in the column direction in the memory cell array 110. The column control circuit 130 includes, for example, an address decoder that decodes the address ADR and a sense amplifier. The sense amplifier can amplify the voltage of the read bit line RBL. For example, when the read word line RWL is activated by the row control circuit 120, the voltage of the read bit line RBL changes according to the data (charge) stored in the associated memory cell MC. Then, the sense amplifier amplifies the change in the voltage of the read bit line RBL to a voltage that can be read by the read/write circuit 140. In addition, the column control circuit 130 can apply a voltage corresponding to data to be written to the memory cell MC to the write bit line WBL. When the write word line WWL is activated by the row control circuit 120, data (charge) is stored in the memory cell MC associated with the write bit line WBL and the activated write word line WWL.

The read/write circuit 140 is configured to execute writing of data to the memory cell array 110 and reading of data from the memory cell array 110. For example, at the time of writing data, the read/write circuit 140 sends a signal (voltage or current) corresponding to data requested to be written to the memory cell array 110 to the memory cell array 110 via the column control circuit 130. In addition, at the time of reading data, the read/write circuit 140 receives a signal (voltage or current) corresponding to the data read from the memory cell array 110 from the memory cell array 110 via the column control circuit 130. Then, the read/write circuit 140 can read (determine) the data stored in the memory cell MC by detecting a variation in voltage or a current of the read bit line RBL. It should be noted that the memory device 100 may independently include a circuit for writing data and a circuit for reading data.

The input/output circuit 150 is an interface circuit that manages communication between the memory device 100 and the memory controller 200. The input/output circuit 150 receives a command CMD, an address ADR, data DT (for example, data requested to be written to the memory cell array 110), a plurality of control signals CNT, and the like from the memory controller 200. The input/output circuit 150 transmits the control signals CNT and the data DT (for example, data read from the memory cell array 110) to the memory controller 200.

The control circuit 160 controls the row control circuit 120, the column control circuit 130, the read/write circuit 140, and the like based on the command CMD and the control signals CNT, and executes an operation to be executed by the memory device 100. The control circuit 160 controls the row control circuit 120, the column control circuit 130, the read/write circuit 140, and the like at timing synchronized with the clock signal CLK. In the memory device 100, writing of data and reading of data are executed at timing synchronized with the clock signal CLK. The clock signal CLK may be generated inside the memory device 100 or may be supplied from the outside. It should be noted that the control circuit 160 may be referred to as a sequencer, an internal controller, or the like.

### <1-1-2> Structure of Memory Device 100

In the following, a structure of the memory device 100 according to the first embodiment will be described. In the following, a case where the extending direction of the memory cell MC corresponds to the X direction, the extending direction of each of the write word line WWL and the read word line RWL corresponds to the Y direction, and the extending direction of each of the write bit line WBL and the read bit line RBL corresponds to the Z direction will be described.

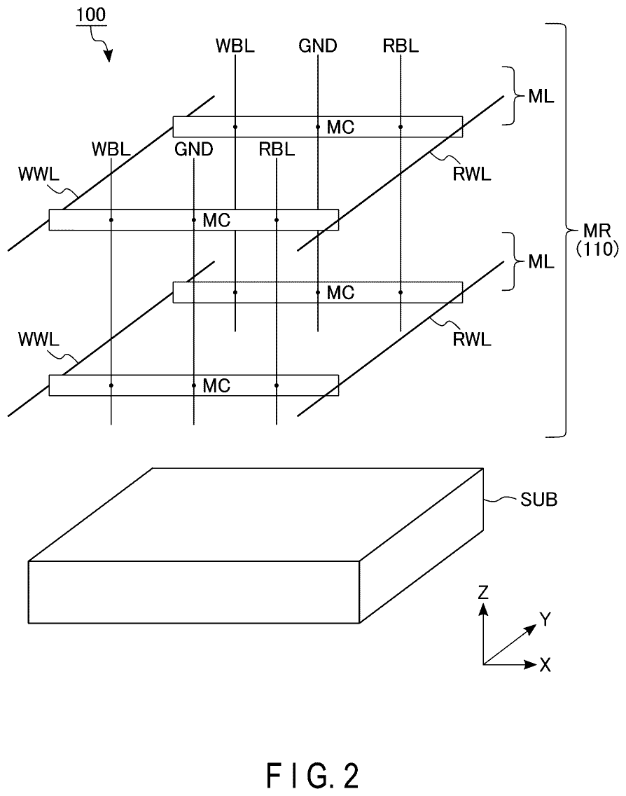

FIG. 2 is a perspective view illustrating an example of a structure of the memory device 100 according to the first embodiment. As illustrated in FIG. 2, the memory device 100 includes a semiconductor substrate SUB. A memory cell array 110 is provided above the semiconductor substrate SUB. Hereinafter, a region in which the memory cell array 110 is provided is referred to as a “memory region MR”. The semiconductor substrate SUB is, for example, a silicon (Si) substrate containing P-type impurities such as boron (B). An insulating layer and an electrode layer (not illustrated) are provided on the upper surface of the semiconductor substrate SUB. The insulating layer and electrode layer constitute a control circuit for controlling the memory device 100. For example, the sense amplifier is provided in a region immediately below the memory cell array 110.

The memory cell array 110 includes a plurality of memory cells MC, a plurality of write word lines WWL, a plurality of read word lines RWL, and a plurality of ground lines GND. Furthermore, the memory cell array 110 includes a plurality of memory layers ML arranged in the Z direction. Each memory layer ML includes a pair of write word line WWL and read word line RWL arranged in the X direction and a plurality of memory cells MC arranged in the Y direction. In each memory layer ML, each of the plurality of memory cells MC is disposed between the pair of write word line WWL and read word line RWL. Then, each of the plurality of memory cells MC is electrically connected to the pair of write word line WWL and read word line RWL.

In the memory region MR, the pair of write bit line WBL and read bit line RBL is arranged in the X direction. In the memory region MR, a plurality of write bit lines WBL are arranged in the Y direction. In the memory region MR, a plurality of read bit lines RBL are arranged in the Y direction. The ground line GND is provided between each of the pair of write bit line WBL and read bit line RBL. That is, in the memory region MR, the plurality of ground lines GND are arranged in the Y direction. In addition, the ground line GND is provided to extend in the Z direction. Each of the pair of write bit line WBL and read bit line RBL and the associated ground line GND is electrically connected to one memory cell MC, in each memory layer ML.

It should be noted that the structure of the memory device 100 according to the first embodiment is not limited to the structure illustrated in FIG. 2. In the memory region MR, each of the number of write word lines WWL arranged in the Z direction and the number of read word lines RWL arranged in the Z direction may be two or more. In addition, in the memory region MR, each of the number of write bit lines WBL arranged in the Y direction and the number of read bit lines RBL arranged in the Y direction may be two or more.

### <1-1-3> Circuit Configuration of Memory Cell MC

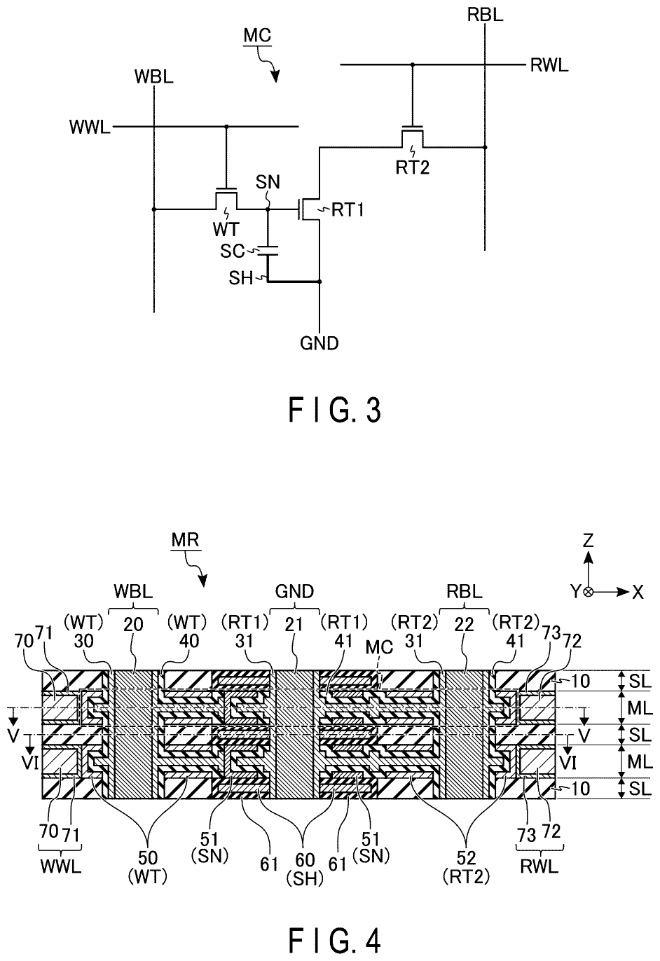

FIG. 3 is a circuit diagram illustrating an example of a circuit configuration of a memory cell MC included in the memory device 100 according to the first embodiment. It should be noted that FIG. 3 illustrates one memory cell MC, a pair of write word line WWL and read word line RWL, a pair of write bit line WBL and read bit line RBL, and a ground line GND. As illustrated in FIG. 3, the memory cell MC has a 3T0C (3-transistor 0-capacitor) configuration. Specifically, the memory cell MC includes, for example, a write transistor WT, read transistors RT1 and RT2, and a storage node SN.

The write transistor WT is, for example, a field-effect NMOS transistor. A gate electrode of the write transistor WT is connected to the write word line WWL. One electrode of the write transistor WT is connected to the write bit line WBL. The other electrode of the write transistor WT is connected to the storage node SN. Each of the one electrode and the other electrode of the write transistor WT functions as a source electrode or a drain electrode according to the voltage supplied (applied) to the write transistor WT.

The read transistor RT1 is, for example, a field-effect NMOS transistor. The gate electrode of the read transistor RT1 corresponds to the storage node SN. One electrode of the read transistor RT1 is connected to the ground line GND. The other electrode of the read transistor RT1 is connected to one electrode of the read transistor RT2. Each of the one electrode and the other electrode of the read transistor RT1 functions as a source electrode or a drain electrode according to the voltage supplied (applied) to the read transistor RT1.

The read transistor RT2 is, for example, a field-effect NMOS transistor. The gate electrode of the read transistor RT2 is connected to the read word line RWL. The other electrode of the read transistor RT2 is connected to the read bit line RBL. Each of the one electrode and the other electrode of the read transistor RT2 functions as a source electrode or a drain electrode according to the voltage supplied (applied) to the read transistor RT2.

The storage node SN has, for example, a parasitic capacitance (<1 fF). The memory cell MC can store data according to the potential of the parasitic capacitance of the storage node SN, that is, the amount of charge accumulated in the storage node SN. As described above, the data is written to the parasitic capacitance of the storage node SN. The leakage current from the storage node SN is limited by the leakage current of the write transistor WT. Therefore, the memory device 100 can read the data of the memory cell MC in a non-destructive manner by reading the current of the read transistor RT1 according to the potential of the storage node SN in the read operation.

In the memory device 100 according to the first embodiment, a shield electrode SH is provided in the vicinity of the memory cell MC. The shield electrode SH is electrically connected to the ground line GND. The shield electrode SH is arranged to face the storage node SN, and suppresses interference between two memory cells MC adjacent in the Z direction. In FIG. 3, the parasitic capacitance between the storage node SN and the shield electrode SH is illustrated as the parasitic capacitance SC. The detailed arrangement of the two memory cells MC adjacent in the Z direction and the shield electrode SH will be described below.

In the write operation, for example, the control circuit 160 applies a predetermined voltage VON1, for example, higher than the power supply voltage VDD by the threshold voltage of the write transistor WT or more to the write word line WWL as a target of the write operation among the plurality of write word lines WWL, and applies a ground voltage VSS or a voltage VOFF1 lower than VSS to the other write word lines WWL. Accordingly, the write transistor WT to which the predetermined voltage VON1 is applied can be in the on state. Then, the control circuit 160 applies the power supply voltage VDD or the ground voltage VSS to the write bit line WBL as a target of the write operation among the plurality of write bit lines WBL according to the data to be written. It should be noted that in the write operation, all the write bit lines WBL in the memory cell array 110 may be the target of the write operation, or some of the write bit lines WBL may be the target of the write operation. The control circuit 160 may turn the write bit line WBL not as the target of the write operation into a floating state.

In the read operation, for example, the control circuit 160 applies the power supply voltage VDD or a predetermined voltage VON2 higher than VDD by the threshold voltage of the read transistor RT2 or more to the read word line RWL as the target of the read operation among the plurality of read word lines RWL, and applies the ground voltage VSS or a voltage VOFF2 lower than VSS to the other read word lines RWL. Accordingly, the read transistor RT2 to which the power supply voltage VDD is applied can be in the on state. In addition, among the plurality of read bit lines RBL, the control circuit 160 applies, for example, VDD to a read bit line RBL as the target of reading, and then turns the read bit line RBL into a floating state. It should be noted that the control circuit 160 may fix the ground line GND to VDD, apply, for example, VSS to the read bit line RBL as the target of reading, and then turn the read bit line RBL into a floating state. Here, in a case where the storage node SN of the memory cell MC as the target of the read operation is charged by the power supply voltage VDD, the read transistor RT1 is in the on state. Then, via the read transistors RT1 and RT2, a current flows from the read bit line RBL to the ground line GND, or the read bit line RBL is discharged. On the other hand, in a case where the storage node SN of the memory cell MC as the target of the read operation is discharged by the ground voltage VSS, the read transistor RT1 is in the off state. In this case, via the read transistors RT1 and RT2, no current flows through the read bit line RBL, and the read bit line RBL is not discharged. It should be noted that in the read operation, all the read bit lines RBL in the memory cell array 110 may be the target of the read operation, or some of the read bit lines RBL may be the target of the read operation. The control circuit 160 may apply, for example, the power supply voltage VDD or the ground voltage VSS to the read bit line RBL not as the target of the read operation.

### <1-1-4> Structure of Memory Cell Array 110

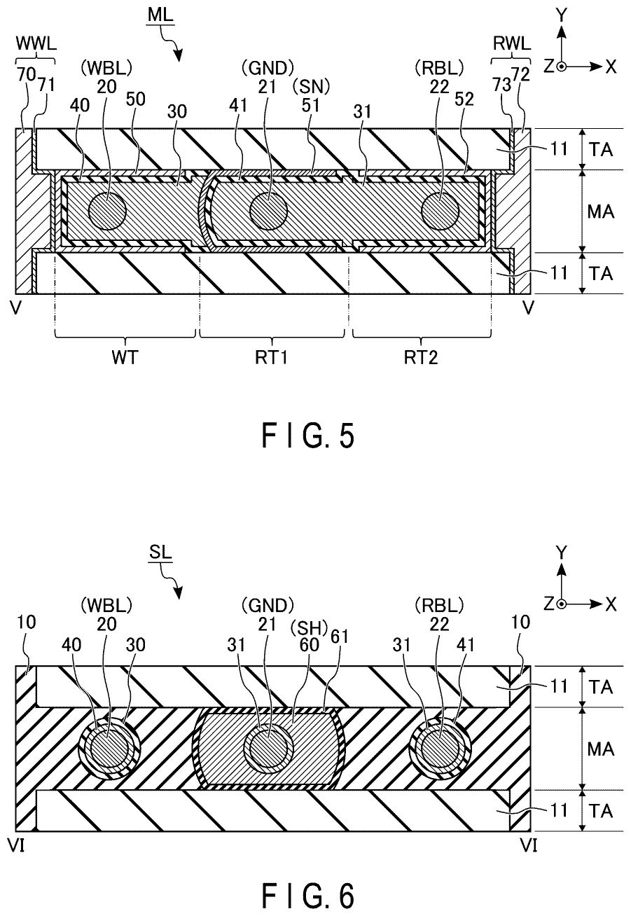

Each of FIGS. 4 to 6 is a cross-sectional view illustrating an example of a structure of the memory cell array 110 included in the memory device 100 according to the first embodiment. FIG. 4 corresponds to the XZ cross-section of the memory cell array 110 provided in the memory region MR in the first embodiment, and extracts and illustrates a region including two memory cells MC adjacent in the Z direction. FIG. 5 corresponds to a cross-section taken along line V-V in FIG. 4. FIG. 6 corresponds to a cross-section taken along line VI-VI in FIG. 4.

As illustrated in FIG. 4, in the memory region MR, a separation layer SL is provided between two memory cells MC adjacent in the Z direction. That is, in the memory region MR, the memory layers ML and the separation layers SL are alternately stacked in the Z direction. The separation layer SL is configured to separate two memory cells MC adjacent in the Z direction. The two memory cells MC adjacent in the Z direction are separated and insulated with the separation layer SL interposed therebetween. In addition, in the memory region MR, the memory cell array 110 includes, for example, an insulating layer 10, conductive members 20, 21, and 22, semiconductor layers 30 and 31, insulating layers 40 and 41, conductive layers 50 and 51, a conductive layer 60, an insulating layer 61, and conductive layers 70 to 73. The insulating layer 10 is provided in each of the plurality of separation layers SL arranged in the Z direction. That is, in the memory region MR, the plurality of insulating layers 10 are arranged in the Z direction. The insulating layer 10 contains, for example, an insulator such as silicon oxide (SiO₂).

Each of the conductive members 20, 21, and 22 is a columnar via wiring line provided to extend in the Z direction and to penetrate the alternately stacked memory layers ML and separation layers SL. The conductive members 20, 21, and 22 are arranged in the X direction. The conductive member 20 functions as a write bit line WBL. The conductive member 21 functions as a ground line GND. The conductive member 22 functions as a read bit line RBL. Each of the conductive members 20, 21, and 22 includes, for example, a metal provided in a central portion in plan view, a barrier conductive film provided on a side surface of a metal column, and a conductive oxide film provided on a side surface of the barrier conductive film. For example, in each of the conductive members 20, 21, and 22, the metal at the central portion contains tungsten (W) or the like, the barrier conductive film contains titanium nitride (TiN) or the like, and the conductive oxide film contains a conductive oxide.

In each of the conductive members 20, 21, and 22, the metal at the central portion extends in the Z direction and is provided in a columnar shape. In each of the conductive members 20, 21, and 22, the barrier conductive film extends in the Z direction and is provided in a substantially cylindrical shape. In each of the conductive members 20, 21, and 22, the conductive oxide extends in the Z direction along the outer peripheral surface (side surface) and is provided in a substantially cylindrical shape. It should be noted that each of the conductive members 20, 21, and 22 may contain ruthenium (Ru), iridium (Ir), or other metals instead of the conductive oxide film. In addition, each of the conductive members 20, 21, and 22 may contain only a conductive oxide, or may contain only ruthenium (Ru), iridium (Ir), or other metals.

The semiconductor layer 30 has a cylindrical first portion extending in the Z direction and provided on the side surface of the conductive member 20 and a second portion extending in the X direction in the memory layer ML. The semiconductor layer 30 is, for example, an oxide semiconductor containing at least one element of gallium (Ga) or aluminum (Al), indium (In), zinc (Zn), and oxygen (O). It should be noted that the semiconductor layer 30 may be another oxide semiconductor.

The insulating layer 40 includes a cylindrical first portion extending in the Z direction and provided on a side surface of the first portion of the semiconductor layer 30, and a second portion provided on an upper surface, a lower surface, both side surfaces in the Y direction, and a side surface on one side (conductive layer 70 side) in the X direction of the second portion of the semiconductor layer 30 in the memory layer ML. The insulating layer 40 contains, for example, an insulator such as silicon oxide (SiO₂).

The conductive layer 50 is provided for each memory layer ML and surrounds the conductive member 20 in plan view. Specifically, the conductive layer 50 of each memory layer ML has a disk-shaped structure that surrounds a part of the semiconductor layer 30 and the insulating layer 40 and is penetrated by the conductive member 20. More specifically, the conductive layer 50 is provided on an upper surface, a lower surface, both side surfaces in the Y direction, and a side surface on one side (conductive layer 70 side) in the X direction of the second portion in the insulating layer 40 in each memory layer ML. The conductive layer 50 faces an upper surface, a lower surface, both side surfaces in the Y direction, and a side surface on one side (conductive layer 70 side) in the X direction in the second portion in the semiconductor layer 30 with the insulating layer 40 interposed therebetween. The conductive layer 50 contains, for example, a conductive material such as titanium nitride (TiN) or a conductive oxide such as indium tin oxide (ITO).

In each memory layer ML, a set of the semiconductor layer 30, the insulating layer 40, and the conductive layer 50 provided around the conductive member 20 constitutes a transistor having a disk-shaped gate-all-around (GAA) structure. A set of the semiconductor layer 30, the insulating layer 40, and the conductive layer 50 provided around the conductive member 20 functions as a write transistor WT. Specifically, in the semiconductor layer 30, a portion facing the conductive layer 50 with the insulating layer 40 interposed therebetween functions as a channel region of the write transistor WT. In the insulating layer 40, a portion sandwiched between the semiconductor layer 30 and the conductive layer 50 functions as a gate insulating film of the write transistor WT. The conductive layer 50 functions as a gate electrode of the write transistor WT.

The semiconductor layer 31 includes a cylindrical first portion extending in the Z direction and provided on a side surface of the conductive member 21, a second portion extending in the X direction in the memory layer ML, and a cylindrical third portion extending in the Z direction and provided on a side surface of the conductive member 22. The semiconductor layer 30 is, for example, an oxide semiconductor containing at least one element of gallium (Ga) or aluminum (Al), indium (In), zinc (Zn), and oxygen (O). It should be noted that the semiconductor layer 31 may be another oxide semiconductor.

The insulating layer 41 includes a cylindrical first portion extending in the Z direction and provided on a side surface of the third portion of the semiconductor layer 31, and a second portion provided on an upper surface, a lower surface, both side surfaces in the Y direction, and both side surfaces in the X direction of the second portion of the semiconductor layer 31 in the memory layer ML. The insulating layer 41 contains, for example, an insulator such as silicon oxide (SiO₂).

The conductive layer 51 is provided for each memory layer ML and surrounds the conductive member 21 in plan view. The conductive layer 52 is provided for each memory layer ML and surrounds the conductive member 22 in plan view. In each memory layer ML, the conductive layers 51 and 52 are separated in the X direction.

The conductive layer 51 of each memory layer ML has a disk-shaped structure that surrounds a part of the semiconductor layer 31 and the insulating layer 41 and is penetrated by the conductive member 21. Specifically, in the second portion of the insulating layer 41, the conductive layer 51 is provided, in the vicinity of the conductive member 21, on an upper surface, a lower surface, and, in the Y direction, both side surfaces, and, in the X direction, a side surface on one side (conductive layer 70 side). The conductive layer 51 faces, in the second portion of the semiconductor layer 31, an upper surface, a lower surface, both side surfaces in the Y direction, and a side surface on one side (conductive layer 70 side) in the X direction in the vicinity of the conductive member 21 with the insulating layer 41 interposed therebetween. A side surface on one side in the X direction of the conductive layer 51 is connected to the semiconductor layer 30. Therefore, the plurality of conductive layers 51 arranged in the Z direction are commonly connected to the conductive member 20 with the semiconductor layer 30 interposed therebetween. The conductive layer 51 contains, for example, a conductive material such as titanium nitride (TiN) or a conductive oxide such as indium tin oxide (ITO). It should be noted that the conductive layer 51 may contain ruthenium (Ru), iridium (Ir), or other metals.

The conductive layer 52 of each memory layer ML has a disk-shaped structure that surrounds another part of the semiconductor layer 31 and the insulating layer 41 and is penetrated by the conductive member 22. Specifically, in the second portion of the insulating layer 41, the conductive layer 52 is provided, in the vicinity of the conductive member 22, on an upper surface, a lower surface, and, in the Y direction, both side surfaces, and, in the X direction, on a side surface on the other side (conductive layer 72 side). The conductive layer 52 faces, in the second portion of the semiconductor layer 31, an upper surface, a lower surface, both side surfaces in the Y direction, and a side surface on the other side (conductive layer 72 side) in the X direction in the vicinity of the conductive member 22 with the insulating layer 41 interposed therebetween. The conductive layer 52 contains, for example, a conductive material such as titanium nitride (TiN) or a conductive oxide such as indium tin oxide (ITO).

In each memory layer ML, a set of the semiconductor layer 31, the insulating layer 41, and the conductive layer 51 provided around the conductive member 21 constitutes a transistor having a disk-shaped GAA structure. A set of the semiconductor layer 31, the insulating layer 41, and the conductive layer 51 provided around the conductive member 21 functions as a read transistor RT1. Specifically, in the semiconductor layer 31, a portion facing the conductive layer 51 with the insulating layer 41 interposed therebetween functions as a channel region of the read transistor RT1. In the insulating layer 41, a portion sandwiched between the semiconductor layer 31 and the conductive layer 51 functions as a gate insulating film of the read transistor RT1. The conductive layer 51 functions as a gate electrode of the read transistor RT1. Furthermore, the conductive layer 51 also functions as the storage node SN.

In each memory layer ML, a set of the semiconductor layer 31, the insulating layer 41, and the conductive layer 52 provided around the conductive member 22 constitutes a transistor having a disk-shaped GAA structure. A set of the semiconductor layer 31, the insulating layer 41, and the conductive layer 52 provided around the conductive member 22 functions as a read transistor RT2. Specifically, in the semiconductor layer 31, a portion facing the conductive layer 52 with the insulating layer 41 interposed therebetween functions as a channel region of the read transistor RT2. In the insulating layer 41, a portion sandwiched between the semiconductor layer 31 and the conductive layer 52 functions as a gate insulating film of the read transistor RT2. The conductive layer 52 functions as a gate electrode of the read transistor RT2. As described above, the read transistors RT1 and RT2 may be configured to share the semiconductor layer 31 and the insulating layer 41.

In each memory layer ML, the configuration corresponding to the write transistor WT, the configuration corresponding to the read transistor RT1, and the configuration corresponding to the read transistor RT2 are arranged in the X direction. In each memory layer ML, a set of the write transistor WT and the read transistors RT1 and RT2 arranged in the X direction constitutes a memory cell MC.

The conductive layer 60 is provided for each separation layer SL and surrounds the conductive member 21 in plan view. In other words, the conductive layer 60 of each separation layer SL has a disk-shaped structure penetrated by the conductive member 21. Specifically, the conductive layer 60 is provided to extend in the X direction and is in contact with a side surface of the semiconductor layer 31. The conductive layer 60 of each separation layer SL is electrically connected to the conductive member 21 with the semiconductor layer 31 interposed therebetween. The conductive layer 60 is provided so as to overlap the conductive layer 51 (storage node SN) in plan view. It is preferable that the conductive layer 60 completely overlap the conductive layer 51 in plan view. The conductive layer 60 contains, for example, a conductive material such as titanium nitride (TiN) or a conductive oxide such as indium tin oxide (ITO).

The insulating layer 61 is provided for each separation layer SL. The insulating layer 61 of each separation layer SL is provided so as to cover a portion excluding a portion penetrated by the conductive member 21 and the semiconductor layer 31 in the conductive layer 60. Specifically, in each separation layer SL, the insulating layer 61 is provided on an upper surface, a lower surface, both side surfaces in the Y direction, and both side surfaces in the X direction of the conductive layer 60. In each separation layer SL, the insulating layer 61 is in contact with the side surface of the first portion of the semiconductor layer 31. The conductive layer 60 is separated and insulated from each of the semiconductor layer 30, the second portions of the semiconductor layers 31 of the two adjacent memory layers ML, the third portion of the semiconductor layer 31, and the conductive layers 50 and 51 of the two adjacent memory layers ML with the insulating layer 61 interposed therebetween. The insulating layer 61 has a composition different from the composition of each of the insulating layers 40 and 41. The insulating layer 61 contains, for example, any one of silicon nitride (SiN), silicon oxynitride (SiON), hafnium oxide (HfO₂), or aluminum oxide (Al₂O₃).

As described above, the conductive layers 60 and 51 separated from each other in the Z direction with the insulating layer 61 interposed therebetween are alternately provided in the Z direction. In other words, in two adjacent memory cells MC in the Z direction, two adjacent conductive layers 51 (storage nodes SN) in the Z direction are adjacent with the conductive layer 60 interposed therebetween. Then, the conductive layer 60 is electrically connected to the conductive member 21. Accordingly, the conductive layer 60 can function as a shield electrode SH. It is preferable that, in plan view, the shield electrode SH be larger than the storage node SN (conductive layer 51) and overlap the entire storage node SN.

The conductive layer 70 is provided for each memory layer ML. In each memory layer ML, the conductive layer 70 is provided on one side in the X direction. The conductive layer 71 is provided, for example, on an upper surface, a lower surface, both side surfaces in the Y direction, and a side surface on the other side in the X direction of the conductive layer 70. In each memory layer ML, the side surface on the other side in the X direction of the conductive layer 71 is in contact with the conductive layer 50. Accordingly, the conductive layer 70 is electrically connected to the conductive layer 50 (gate electrode of the write transistor WT) with the conductive layer 71 interposed therebetween. The set of conductive layers 70 and 71 functions as a write word line WWL. The conductive layer 70 is, for example, a conductor such as tungsten (W). The conductive layer 71 is, for example, a barrier conductive film such as titanium nitride (TiN).

The conductive layer 72 is provided for each memory layer ML. In each memory layer ML, the conductive layer 72 is provided on the other side in the X direction. The conductive layer 73 is provided, for example, on an upper surface, a lower surface, both side surfaces in the Y direction, and a side surface on one side in the X direction of the conductive layer 72. In each memory layer ML, the side surface on one side in the X direction of the conductive layer 73 is in contact with the conductive layer 52. Accordingly, the conductive layer 72 is electrically connected to the conductive layer 52 (gate electrode of the read transistor RT2) with the conductive layer 73 interposed therebetween. The set of conductive layers 72 and 73 functions as a read word line RWL. The conductive layer 72 is, for example, a conductor such as tungsten (W). The conductive layer 73 is, for example, a barrier conductive film such as titanium nitride (TiN).

As illustrated in FIG. 5, the memory cell array 110 includes a plurality of insulating members 11 in the memory layer ML. Each insulating member 11 is provided to extend in the X direction along the memory cell MC. The plurality of insulating members 11 are arranged in the Y direction. Although not illustrated, each insulating member 11 is further provided to penetrate the memory layers ML and the separation layers SL extending in the Z direction and alternately stacked in the Z direction. Accordingly, each insulating member 11 electrically divides the plurality of memory cells MC (not illustrated) arranged in the Y direction. In the present specification, an area extending in the X direction and including the memory cell MC is referred to as a “memory area MA”. An area extending in the X direction and including the insulating member 11 is referred to as a “trench area TA”. That is, the memory area MA and the trench area TA are alternately arranged in the Y direction.

In the XY cross-section, the conductive layers 70 and 71 corresponding to the write word line WWL have portions extending in the Y direction, over the memory area MA and the trench area TA alternately arranged in the Y direction. In the XY cross-section, the conductive layers 72 and 73 corresponding to the read word line RWL have portions extending in the Y direction, over the memory area MA and the trench area TA alternately arranged in the Y direction. One side (conductive layer 70 side) of each insulating member 11 is in contact with a write word line WWL (for example, the conductive layer 71). The other side (conductive layer 72 side) of each insulating member 11 is in contact with a read word line RWL (for example, the conductive layer 73).

In the XY cross-section, a side surface portion on one side in the X direction of the semiconductor layer 30 is formed linearly along the conductive layer 70, for example. In the XY cross-section, a side surface portion on the other side in the X direction of the semiconductor layer 30 is formed in an arc shape along a circle centered on the center position of the conductive member 21 (via wiring line). In the XY cross-section, in the insulating layer 40, a portion provided in the vicinity of the boundary between the write transistor WT and the read transistor RT1 is in contact with two insulating members 11 adjacent in the Y direction. In the XY cross-section, the conductive layer 50 is in contact with two insulating members 11 adjacent in the Y direction.

In the XY cross-section, a side surface portion on one side in the X direction of the semiconductor layer 31 is formed in an arc shape along a circle centered on the center position of the conductive member 21 (via wiring line). In the XY cross-section, a side surface portion on the other side in the X direction of the semiconductor layer 31 is formed linearly along the conductive layer 72, for example. In the XY cross-section, in the insulating layer 41, a portion provided in the vicinity of the boundary between the read transistors RT1 and RT2 is in contact with two insulating members 11 adjacent in the Y direction. In the XY cross-section, side surface portions on both sides in the Y direction of the conductive layer 51 are in contact with two insulating members 11 adjacent in the Y direction. In addition, in the XY cross-section, a side surface portion on one side in the X direction of the conductive layer 51 is formed in an arc shape along a circle centered on the center position of the conductive member 21 (via wiring line). In the XY cross-section, side surface portions on both sides in the Y direction of the conductive layer 52 are in contact with two insulating members 11 adjacent in the Y direction. In addition, in the XY cross-section, a side surface portion on the other side in the X direction of the conductive layer 52 is formed linearly along the conductive layer 72.

Although not illustrated, in the XY cross-section, a side surface portion on the other side in the X direction of the conductive layer 50 is formed in an arc shape along a circle centered on the center position of the conductive member 21 (via wiring line). Although not illustrated, in the XY cross-section, side surface portions on both sides in the X direction of the conductive layer 51 are formed in an arc shape along a circle centered on the center position of the conductive member 21 (via wiring line). Although not illustrated, in the XY cross-section, a side surface portion on one side in the X direction of the conductive layer 52 is formed in an arc shape along a circle centered on the center position of the conductive member 21 (via wiring line).

As illustrated in FIG. 6, the memory cell array 110 includes a plurality of insulating members 11 in the separation layer SL, as in the memory layer ML. The insulating layer 10 is provided to overlap the write word line WWL, the read word line RWL, and the memory cell MC in the Z direction in the separation layer SL. Then, the insulating layer 10 has a portion penetrated by the conductive member 20, the semiconductor layer 30, and the insulating layer 40, and a portion penetrated by the conductive member 22, the semiconductor layer 31, and the insulating layer 41. Furthermore, the insulating layer 10 is divided into one side and the other side in the X direction with a set of the conductive layer 60 and the insulating layer 61 interposed.

In the XY cross-section, side surface portions on both sides in the Y direction of the conductive layer 60 are formed linearly along the two insulating members 11 adjacent in the Y direction. In addition, in the XY cross-section, each of the side surface portion on one side in the X direction of the conductive layer 60 and the side surface portion on the other side in the X direction of the conductive layer 60 is formed in an arc shape along a circle centered on the center position of the conductive member 21 (via wiring line). In the XY cross-section, the insulating layer 61 is provided so as to surround the outer periphery of the conductive layer 60. Specifically, in the XY cross-section, the insulating layer 61 has a portion sandwiched between the insulating member 11 on one side in the Y direction and the conductive layer 60, a portion sandwiched between the insulating member 11 on the other side in the Y direction and the conductive layer 60, and a portion sandwiched between the insulating layer 10 and the conductive layer 60. The width in the Y direction between both end portions in the Y direction of the insulating layer 61 is substantially equal to the width in the Y direction of the memory area MA. The width in the X direction between both end portions in the X direction of the insulating layer 61 is larger than the width in the Y direction of the memory area MA.

It should be noted that in the present specification, let the “conductive oxide” include, for example, indium tin oxide (ITO), indium zinc oxide (IZO), ruthenium oxide (RuO₂), iridium oxide (IrO₂), or another conductive material containing oxygen. In the memory cell array 110, the gate electrode of the write transistor WT may be connected to the write word line WWL with a conductive oxide interposed therebetween. In addition, the gate electrode of the read transistor RT2 may be connected to the read word line RWL with a conductive oxide interposed therebetween.

### <1-2> Manufacturing Method

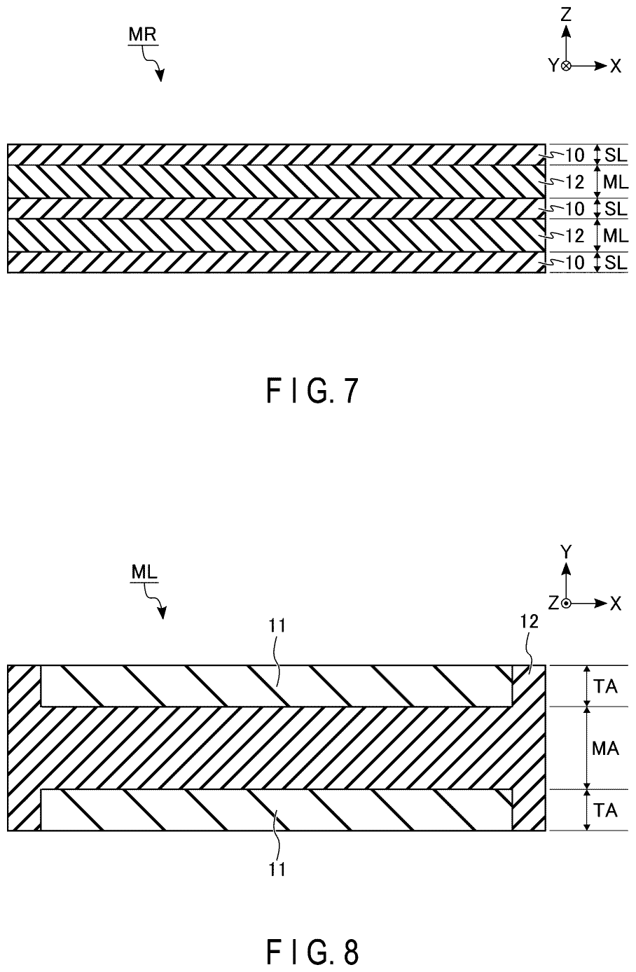

Next, as a method for manufacturing the memory device 100 according to the first embodiment, a process of forming the memory cell array 110 will be described with reference to FIGS. 7 to 24. Each of FIGS. 7 to 24 is a cross-sectional view illustrating an example of a structure in a step for manufacturing the memory device 100 according to the first embodiment. Each of FIGS. 7 to 24 illustrates the same region as any one of the memory region MR illustrated in FIG. 4, the memory layer ML illustrated in FIG. 5, or the separation layer SL illustrated in FIG. 6. It should be noted that in the present specification, “processing via a predetermined hole” corresponds to executing processing in a state where another hole is covered with a mask, a sacrificial member, or the like. That is, in a case where processing via a predetermined hole is executed, let processing on the configuration associated with another hole be not performed or be suppressed.

First, as illustrated in FIG. 7, the insulating layers 10 and the sacrificial members 12 are alternately stacked. In the present step, the layer provided with the insulating layer 10 corresponds to the separation layer SL, and the layer provided with the sacrificial member 12 corresponds to the memory layer ML. The insulating layer 10 is, for example, silicon oxide (SiO₂). The sacrificial member 12 is, for example, silicon nitride (SiN).

Next, as illustrated in FIG. 8, the insulating member 11 that divides the stacked insulating layers 10 and sacrificial members 12 is formed in the trench area TA. Specifically, first, the insulating layer 10 and the sacrificial member 12 provided in the area corresponding to the insulating member 11 are removed by anisotropic etching processing such as reactive ion etching (RIE). Then, an insulator is embedded by chemical vapor deposition (CVD) or the like in the trench portion formed by the etching processing. Accordingly, the insulating member 11 is formed in each trench area TA. The insulating member 11 is, for example, silicon oxide (SiO₂).

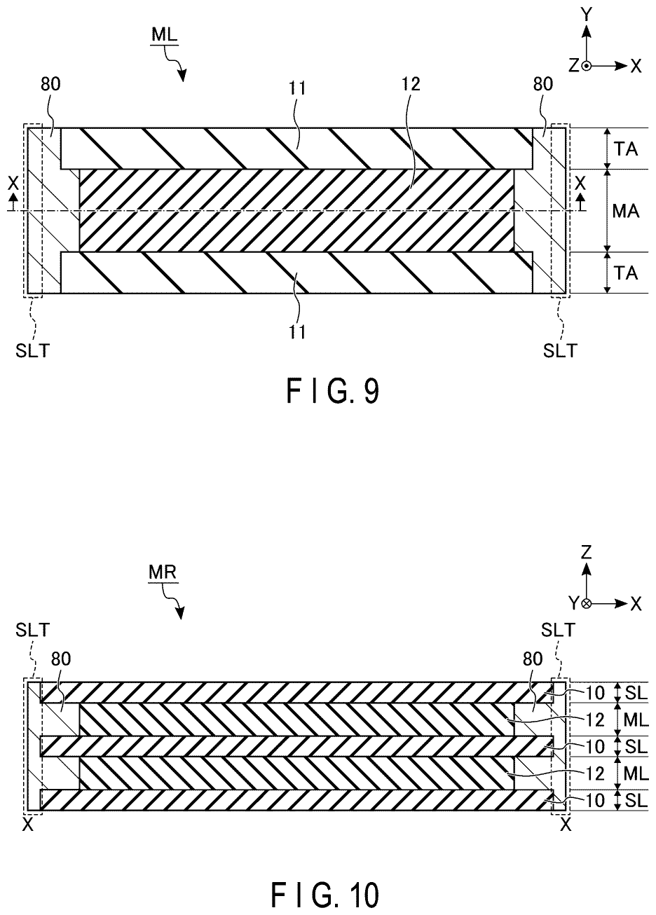

Next, as illustrated in FIG. 9, (1) at least two slits SLT are formed, (2) a recessed portion is formed by selectively removing a part of the sacrificial member 12 in the memory area MA, and (3) a sacrificial member 80 is embedded in the formed recessed portion. In the present step, the two slits SLT are formed by, for example, anisotropic etching processing such as RIE so as to remove the alternately stacked insulating layers 10 and sacrificial members 12 in each of the vicinity of the region corresponding to the write word line WWL and the vicinity of the region corresponding to the read word line RWL. In the present step, the recessed portion is formed, by wet etching processing or the like, so that the sacrificial member 12 of each memory layer ML is separated in each of the plurality of memory areas MA arranged at least in the Y direction. FIG. 10 corresponds to a cross-section taken along line X-X in FIG. 9. As illustrated in FIG. 10, the sacrificial members 80 provided on each of both sides in the X direction is formed so as to embed a recessed portion of each memory layer ML. The sacrificial member 80 is, for example, amorphous silicon (aSi).

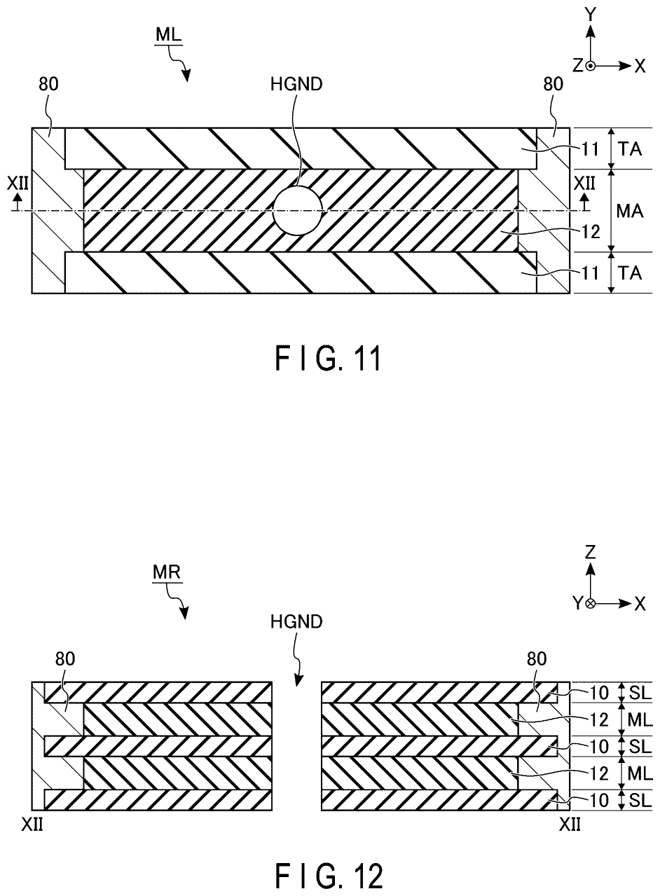

Next, as illustrated in FIG. 11, a hole HGND is formed in a portion corresponding to the ground line GND in the memory area MA. FIG. 12 corresponds to a cross-section taken along line XII-XII in FIG. 11. As illustrated in FIG. 12, the hole HGND is formed, by anisotropic etching processing such as RIE, so as to penetrate the insulating layers 10 and the sacrificial members 12 that extend in the Z direction and are stacked.

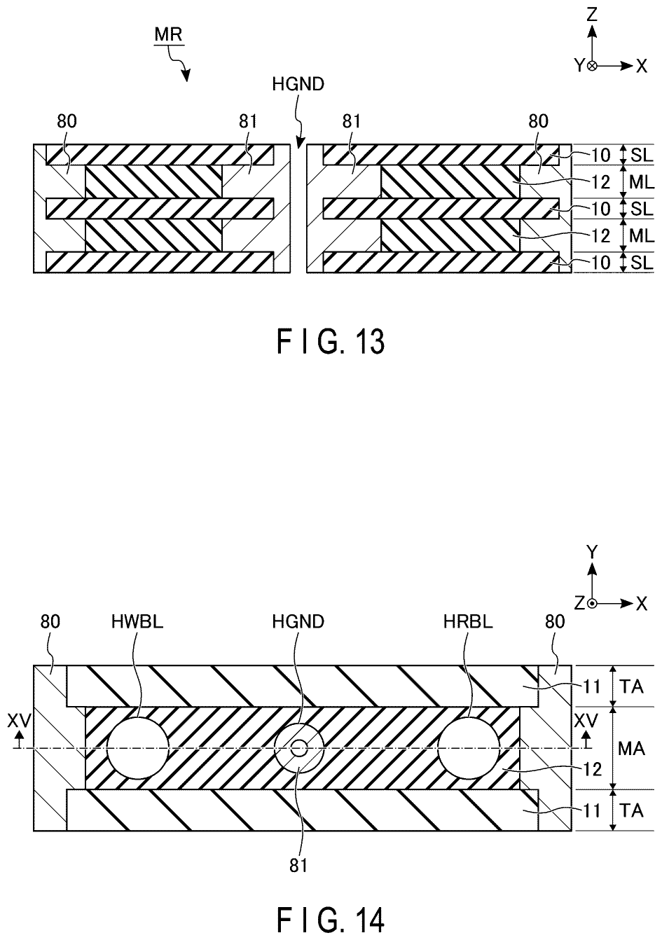

Next, as illustrated in FIG. 13, (1) a recessed portion is formed by selectively removing a part of the sacrificial member 12 of each memory layer ML through the hole HGND, and (2) a sacrificial member 81 is embedded in the formed recessed portion. The recessed portion formed in the present step corresponds to a place where the read transistor RT1 is formed. The sacrificial member 81 covers a side surface of the insulating layer 10 in the hole HGND. It should be noted that in the present step, the sacrificial member 81 may be formed so as to embed the hole HGND. The sacrificial member 81 is, for example, amorphous silicon (aSi).

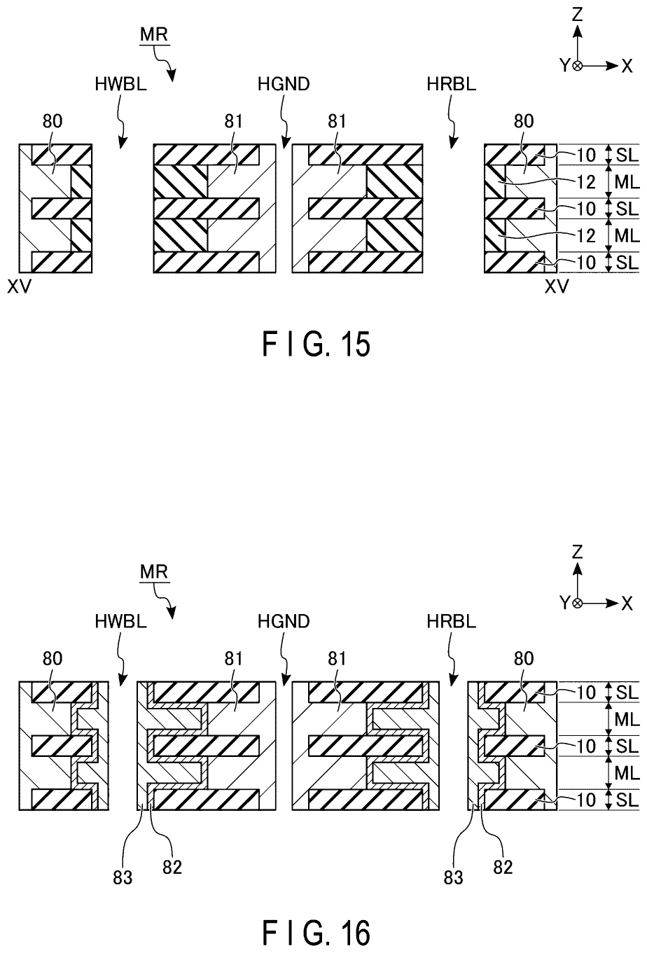

Next, as illustrated in FIG. 14, in the memory area MA, (1) a hole HWBL is formed in a portion corresponding to the write bit line WBL, and (2) a hole HRBL is formed in a portion corresponding to the read bit line RBL. FIG. 15 corresponds to a cross-section taken along line XV-XV in FIG. 14. As illustrated in FIG. 15, each of the holes HWBL and HRBL is formed, by anisotropic etching processing such as RIE, so as to penetrate the insulating layers 10 and the sacrificial members 12 that extend in the Z direction and are stacked.

Next, as illustrated in FIG. 16, (1) recessed portions are formed by selectively removing the sacrificial member 12 of each memory layer ML through the holes HWBL and HRBL, and (2) the conductive film 82 and the sacrificial member 83 are sequentially formed so as to fill the formed recessed portions. In the present step, for example, wet etching processing is used to form the recessed portion. The recessed portion formed corresponding to the hole HWBL corresponds to a place where the write transistor WT is formed. In the present step, the recessed portion formed corresponding to the hole HRBL corresponds to a place where the read transistor RT2 is formed. The conductive film 82 of each of the holes HWBL and HRBL is in contact with each of the sacrificial members 80 and 81 in the memory layer ML. In addition, the conductive film 82 covers the upper surface, the lower surface, both side surfaces in the X direction, and both side surfaces in the Y direction of the insulating layer 10 in each of the holes HWBL and HRBL. In the present step, the sacrificial member 83 may be formed so as to embed the holes HWBL and HRBL. Each of the conductive film 82 and the sacrificial member 83 is formed by, for example, CVD or the like. The conductive film 82 is, for example, titanium nitride (TiN). The sacrificial member 83 is, for example, amorphous silicon (aSi).

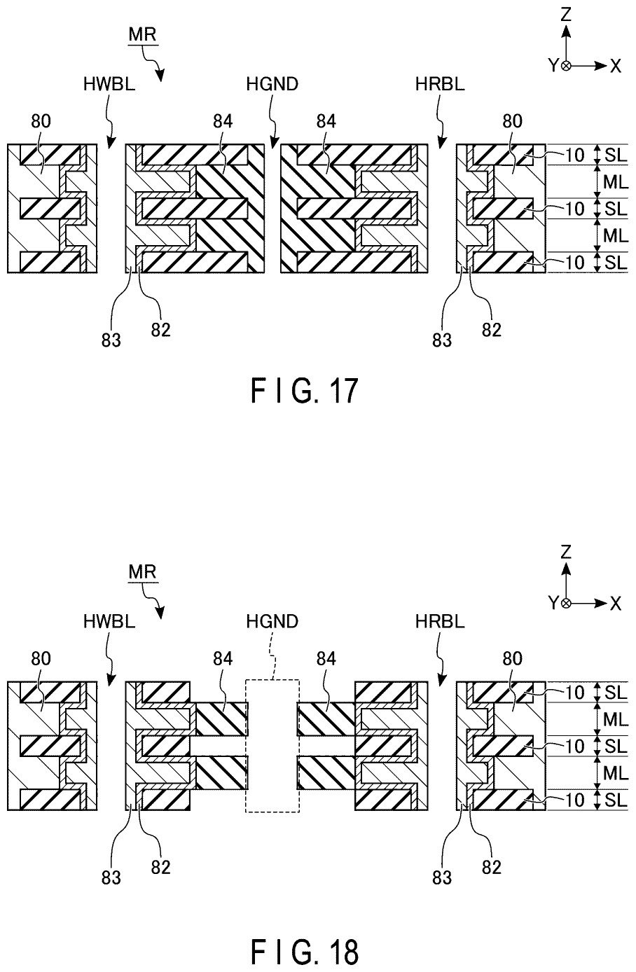

Next, as illustrated in FIG. 17, (1) the sacrificial member 81 provided corresponding to the hole HGND is selectively removed, and (2) a sacrificial member 84 is formed so that the recessed portion in contact with the hole HGND is filled in each memory layer ML. In the present step, for example, wet etching processing is used to remove the sacrificial member 81. In each memory layer ML, the sacrificial member 84 is in contact with each of the conductive film 82 provided in the recessed portion in contact with the hole HWBL and the conductive film 82 provided in the recessed portion in contact with the hole HRBL. The sacrificial member 84 is, for example, silicon nitride (SiN). In the present step, the sacrificial member 84 may be formed so as to embed the hole HGND.

Next, as illustrated in FIG. 18, (1) a part of the sacrificial member 84 provided in the hole HGND is removed, so that the insulating layer 10 is exposed on the side surface of the hole HGND, and (2) a part of the insulating layer 10 of each separation layer SL is selectively removed through the hole HGND. In the present step, for example, wet etching processing is used to remove the sacrificial member 84. In the present step, the recessed portion that is in contact with the hole HGND and formed in the separation layer SL corresponds to a place where the shield electrode SH is formed.

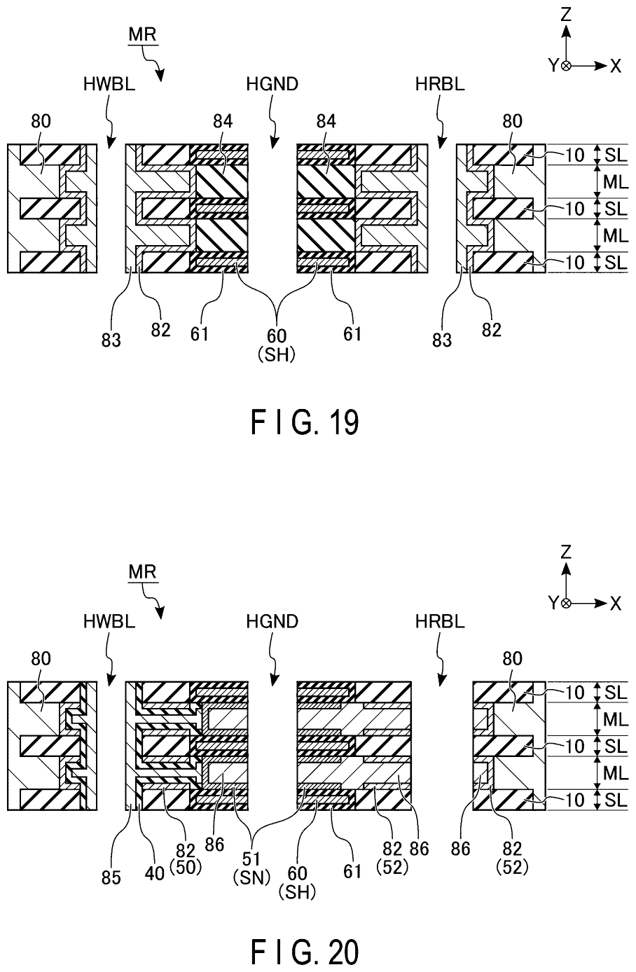

Next, as illustrated in FIG. 19, (1) an insulating film corresponding to the insulating layer 61 and a conductive film corresponding to the conductive layer 60 are formed, and (2) the insulating film and the conductive film provided on the side surface portion of the hole HGND are removed. Accordingly, a structure corresponding to the shield electrode SH is formed. In addition, by the present step, the side surface of the sacrificial member 84 of each memory layer ML is exposed in the hole HGND. In the present step, for example, CVD is used to form the insulating film and the conductive film.

Next, as illustrated in FIG. 20, the sacrificial member 84 of each memory layer ML is selectively removed through the hole HGND, and in each memory layer ML, conductive layers 50, 51, and 52 are formed, an insulating layer 40 is formed, and sacrificial members 85 and 86 are formed. The structure illustrated in FIG. 20 can be formed by appropriately executing etching processing and film formation processing using the holes HGND, HWBL, and HRBL. The conductive layer 51 is, for example, a conductive oxide such as indium tin oxide (ITO). The conductive layers 50 and 52 of each memory layer ML are formed by processing the conductive film 82. The sacrificial member 85 is provided so as to cover the insulating layer 40 at least in the hole HWBL. The sacrificial member 86 is provided in each memory layer ML so as to fill a space sandwiched by the conductive layers 51 formed in a disk shape, a space sandwiched by the conductive layers 52 formed in a disk shape, and a space between the conductive layers 51 and 52. Each of the sacrificial members 85 and 86 is, for example, amorphous silicon (aSi).

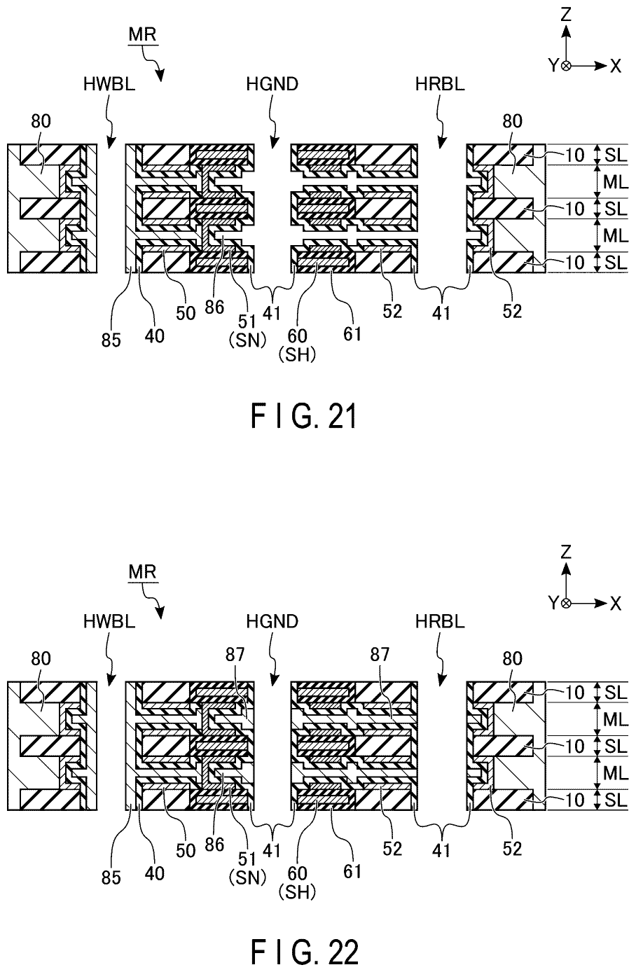

Next, as illustrated in FIG. 21, (1) a part of the conductive layer 51 provided in the memory layer ML is removed through the hole HGND, (2) the sacrificial member 86 of each memory layer ML is selectively removed, and (3) an insulating layer 41 is formed through the holes HGND and HRBL. The conductive layer 51 processed in the present step corresponds to the shape of the conductive layer 51 (storage node SN) illustrated in FIG. 4. For example, wet etching processing is used to remove the conductive layer 51. The insulating layer 41 is formed as a film by, for example, CVD or the like.

Next, as illustrated in FIG. 22, in each memory layer ML, a sacrificial member 87 is embedded in a space sandwiched in the Z direction by the insulating layers 41. The sacrificial member 87 is formed as a film by, for example, CVD or the like. In the present step, the sacrificial members 87 formed on the side surface portions of the holes HGND and HRBL are removed by etch back processing. The sacrificial member 87 is, for example, amorphous silicon (aSi).

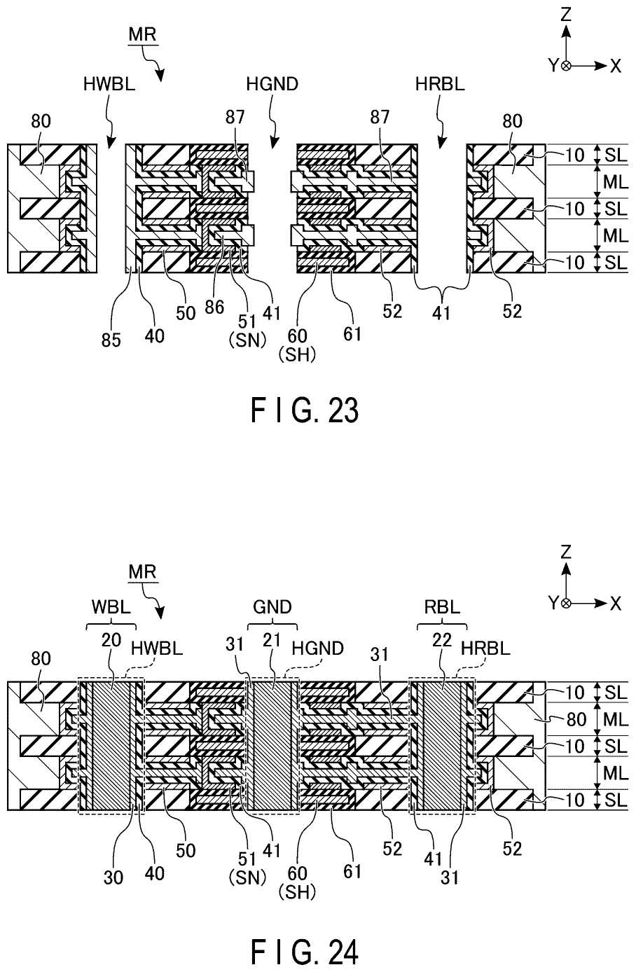

Next, as illustrated in FIG. 23, the insulating layer 41 formed on the side surface portion of the hole HGND in each separation layer SL is selectively removed through the hole HGND. Accordingly, a part of the conductive layer 60 is exposed in a portion corresponding to each separation layer SL in the hole HGND. For example, wet etching processing is used to remove the insulating layer 41.

Next, as illustrated in FIG. 24, (1) the sacrificial members 85 and 87 are selectively removed, (2) semiconductor layers 30 and 31 are formed, and (3) conductive members 20, 21, and 22 are respectively embedded in the holes HWBL, HGND, and HRBL. Thereafter, the sacrificial member 80 is removed, and a configuration corresponding to the write word line WWL and the read word line RWL is formed. As a result, the structure of the memory cell array 110 illustrated in FIGS. 4 to 6 is completed.

### <1-3> Advantageous Effects of First Embodiment

According to the memory device 100 according to the first embodiment, it is possible to provide a low-cost three-dimensionally stacked memory. In the following, details of the advantageous effects of the memory device 100 according to the first embodiment will be described using a comparative example.

As a memory cell having a gain cell structure, a memory cell MC having a 3 transistor 0 capacitor (3T0C) configuration is known. As compared with the memory cell having the 1T1C configuration, the memory cell having the 3T0C configuration is expected, due to capacitor-less design, to have (1) improved tWT (write time), (2) lower power consumption, and (3) improved cell size scalability with respect to higher stacking.

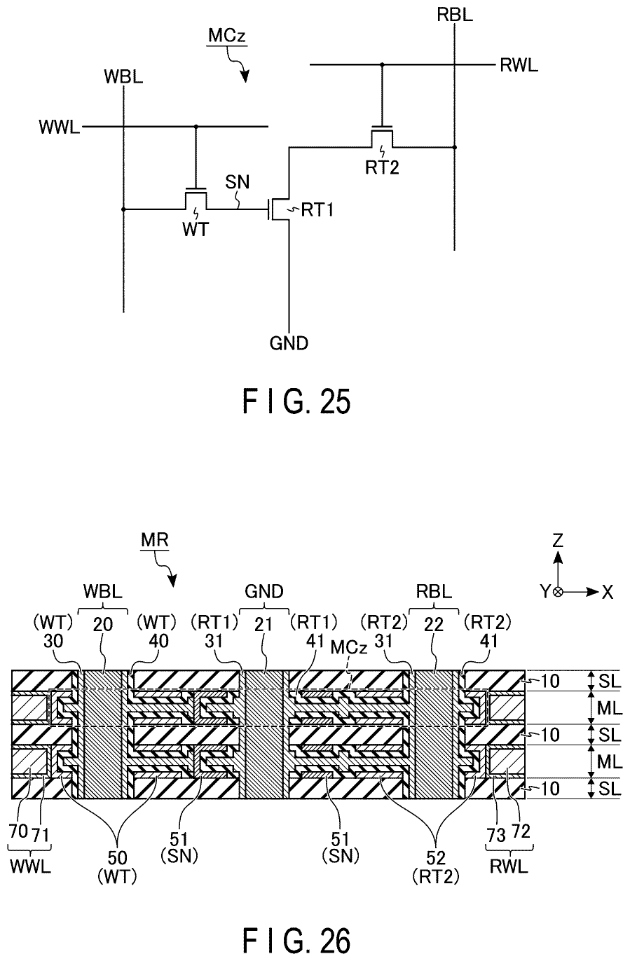

FIG. 25 is a circuit diagram illustrating an example of a circuit configuration of a memory cell MCz included in a memory device 100 according to a comparative example. As illustrated in FIG. 25, the memory cell MCz has a configuration in which the shield electrode SH is omitted from the circuit configuration of the memory cell MC illustrated in FIG. 3. FIG. 26 is a cross-sectional view illustrating an example of a structure of a memory cell array 110 included in the memory device 100 according to the comparative example. As illustrated in FIG. 26, in the memory device 100 according to the comparative example, the shield electrode SH is not disposed in the separation layer SL. That is, two memory cells MCz adjacent in the Z direction are adjacent with the insulating layer 10 interposed therebetween.

In the memory cell MCz in the comparative example, when the signals (“0” or “1”) of the upper and lower memory cells MCz change due to writing, the potential of the storage node SN is affected by coupling. Therefore, in the memory cell MCz of the comparative example, the potential of the storage node SN interferes with two memory cells MCz adjacent in the Z direction. In a case where such memory cells MCz are to be stacked higher, it is necessary to widen the stacking interval of the memory cells MCz in order to suppress the influence of interference. However, widening the stacking interval of the memory cells MCz can be a factor in an increase in the size and an increase in the cost of the memory cell array.

On the other hand, the memory device 100 according to the first embodiment has a configuration in which a shield electrode SH is formed in each of the two separation layers SL adjacent to the storage node SN in the Z direction, and the shield electrode SH is electrically connected to the ground line GND. The shield electrode SH can suppress an influence caused by a change in the potential of the storage node SN due to writing in the memory cells MC adjacent in the Z direction. That is, interference between the two memory cells MC arranged above and below the shield electrode SH can be suppressed.

As a result, the memory device 100 according to the first embodiment can reduce the pitch of the memory cells MC arranged in the Z direction, and can provide a high-density and low-cost three-dimensional stacked memory. Furthermore, since the shield electrode SH can add capacitance (<1 fF) between the storage node SN and the ground line GND, the shield electrode SH can improve noise resistance. It should be noted that since the shield electrode SH is formed only in the upper and lower regions of the storage node SN, the parasitic capacitance of the write word line WWL and the read word line RWL does not increase. That is, the deterioration of the characteristics of the memory cell MC due to the addition of the shield electrode SH can be suppressed.

### <2> SECOND EMBODIMENT

In a memory device 100 according to a second embodiment, both side surfaces in the X direction of a shield electrode SH are provided in a concave lens shape (arc shape) in plan view. In the following, details of the memory device 100 according to the second embodiment will be described mainly on the differences from the first embodiment.

### <2-1> Configuration

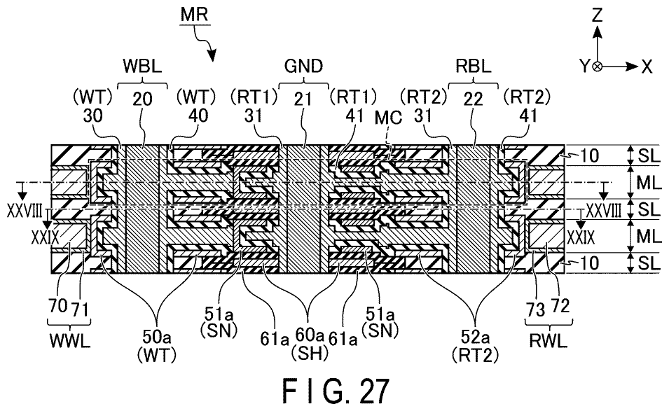

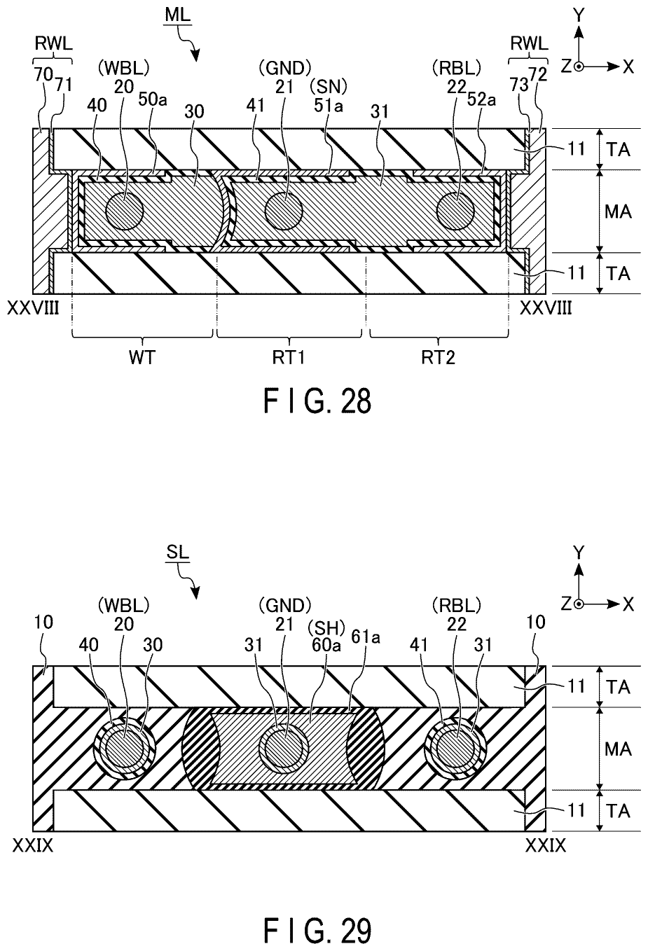

First, a configuration of a memory device 100 according to a second embodiment will be described with reference to FIGS. 27 to 29. Each of FIGS. 27 to 29 is a cross-sectional view illustrating an example of a structure of a memory cell array 110 included in the memory device 100 according to the second embodiment. FIG. 27 corresponds to the XZ cross-section of the memory cell array 110 provided in the memory region MR in the second embodiment, and extracts and illustrates a region including two memory cells MC adjacent in the Z direction. FIG. 28 corresponds to a cross-section taken along line XXVIII-XXVIII in FIG. 27. FIG. 29 corresponds to a cross-section taken along line XXIX-XXIX in FIG. 27. The memory device 100 according to the second embodiment has the same configuration as the memory device 100 according to the first embodiment. On the other hand, in the memory device 100 according to the second embodiment, the shapes of the conductive layers 50, 51, and 60 and the insulating layer 61 are mainly different from those of the memory device 100 according to the first embodiment. Hereinafter, the conductive layers 50, 51, and 60, and the insulating layer 61 included in the memory device 100 according to the second embodiment are referred to as conductive layers 50a, 51a, and 60a, and an insulating layer 61a, respectively.

As illustrated in FIG. 27, in each memory layer ML, the conductive layer 50a and the conductive layer 52a have shapes protruding into the separation layer SL described in the first embodiment. Specifically, the width in the Z direction between the upper end and the lower end of the conductive layer 50a is wider than the width in the Z direction of the write word line WWL (conductive layers 70 and 71). The width in the Z direction between the upper end and the lower end of the conductive layer 52a is wider than the width in the Z direction of the read word line RWL (conductive layers 72 and 73). It should be noted that the width in the Z direction between the upper end and the lower end of the conductive layer 50a is, for example, substantially equal to the width in the Z direction between the upper end and the lower end of the conductive layer 52a.

Therefore, in the insulating layer 10, the thickness in the Z direction of a portion sandwiched between two conductive layers 50a adjacent in the Z direction is thinner than the thickness in the Z direction of a portion sandwiched between two write word lines WWL adjacent in the Z direction. Similarly, in the insulating layer 10, the thickness in the Z direction of a portion sandwiched between two conductive layers 52a adjacent in the Z direction is thinner than the thickness in the Z direction of a portion sandwiched between two read word lines RWL adjacent in the Z direction. In addition, the interval between the upper end and the lower end in the Z direction of the conductive layer 51a is narrower than each of the interval between the upper end and the lower end in the Z direction of the conductive layer 50a and the interval between the upper end and the lower end in the Z direction of the conductive layer 52a.

Then, the insulating layer 61a is provided to be closed at each of a portion sandwiched between two conductive layers 50a adjacent in the Z direction and a portion sandwiched between two conductive layers 52a adjacent in the Z direction. Therefore, the conductive layer 60a is disposed away from each of the conductive layers 50a and 52a by an amount corresponding to the closing of the insulating layer 61a in plan view. Accordingly, the conductive layer 60a is not included in each of a portion sandwiched between two conductive layers 50a adjacent in the Z direction and a portion sandwiched between two conductive layers 52a adjacent in the Z direction.

As illustrated in FIG. 28, in the XY cross-section, a side surface portion on the other side (conductive layer 72) in the X direction of the semiconductor layer 30 of the second embodiment is formed in an arc shape along a circle centered on the center position of the conductive member 20 (via wiring line). Although not illustrated, in the XY cross-section, a side surface portion on the other side in the X direction of the conductive layer 50a is formed in an arc shape along a circle centered on the center position of the conductive member 20 (via wiring line). In the XY cross-section, a side surface portion on one side (conductive layer 70 side) in the X direction of the semiconductor layer 31 of the second embodiment is formed in an arc shape along a circle centered on the center position of the conductive member 20 (via wiring line). Although not illustrated, in the XY cross-section, a side surface portion on one side in the X direction of the conductive layer 51a is formed in an arc shape along a circle centered on the center position of the conductive member 20 (via wiring line). Although not illustrated, an end portion on the other side in the X direction of the conductive layer 50a and an end portion on one side in the X direction of the conductive layer 51a face each other, with a fixed distance maintained. Although not illustrated, in the XY cross-section, a side surface portion on the other side in the X direction of the conductive layer 51a is formed in an arc shape along a circle centered on the center position of the conductive member 22 (via wiring line). Although not illustrated, in the XY cross-section, a side surface portion on one side in the X direction of the conductive layer 52a is formed in an arc shape along a circle centered on the center position of the conductive member 22 (via wiring line).

As illustrated in FIG. 29, in the XY cross-section, a side surface portion on one side in the X direction of the conductive layer 60a is formed in an arc shape along a circle centered on the center position of the conductive member 20 (via wiring line). In the XY cross-section, a side surface portion on the other side in the X direction of the conductive layer 60a is formed in an arc shape along a circle centered on the center position of the conductive member 22 (via wiring line). In the XY cross-section, each of the side surface portion on one side in the X direction of the insulating layer 61a and the side surface portion on the other side in the X direction of the insulating layer 61a is formed in an arc shape along a circle centered on the center position of the conductive member 21 (via wiring line). In addition, in the XY cross-section, the shape of each of the portion on one side in the X direction of the insulating layer 61a and the portion on the other side in the X direction of the insulating layer 61a is a convex lens shape. The width in the Y direction between both end portions in the Y direction of the insulating layer 61a is substantially equal to the width in the Y direction of the memory area MA. The width in the X direction between both end portions in the X direction of the insulating layer 61a is larger than the width in the Y direction of the memory area MA. Furthermore, in the insulating layer 61a, the width in the X direction of a portion sandwiched between the conductive layer 60a and the insulating layer 10 is narrower than the width in the X direction of a portion sandwiched between the conductive layer 60a and the insulating member 11.

Other configurations of the memory device 100 according to the second embodiment are similar to those of the memory device 100 according to the first embodiment.

### <2-2> Manufacturing Method

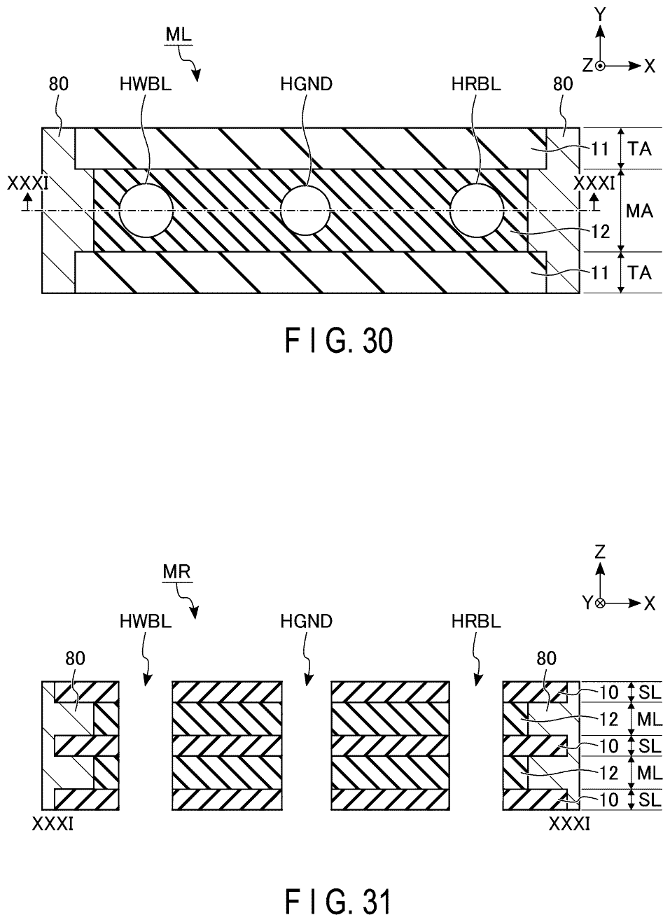

Next, as a method for manufacturing the memory device 100 according to the second embodiment, a process of forming the memory cell array 110 will be described with reference to FIGS. 30 to 41. Each of FIGS. 30 to 41 is a cross-sectional view illustrating an example of a structure in a step for manufacturing the memory device according to the second embodiment. Each of FIGS. 30 to 41 illustrates the same region as any one of the memory region MR illustrated in FIG. 27, the memory layer ML illustrated in FIG. 28, or the separation layer SL illustrated in FIG. 29.

In the method for manufacturing the memory device 100 according to the second embodiment, first, the processing described with reference to FIGS. 7 to 10 in the first embodiment is executed, and the structure illustrated in FIG. 10 is formed.

Next, as illustrated in FIG. 30, in the memory area MA, a hole HWBL is formed in a portion corresponding to the write bit line WBL, a hole HGND is formed in a portion corresponding to the ground line GND, and a hole HRBL is formed in a portion corresponding to the read bit line RBL. FIG. 31 corresponds to a cross-section taken along line XXXI-XXXI in FIG. 30. As illustrated in FIG. 31, each of the holes HWBL, HGND, and HRBL is formed, by anisotropic etching processing such as RIE, so as to penetrate the insulating layers 10 and the sacrificial members 12 that extend in the Z direction and are stacked.

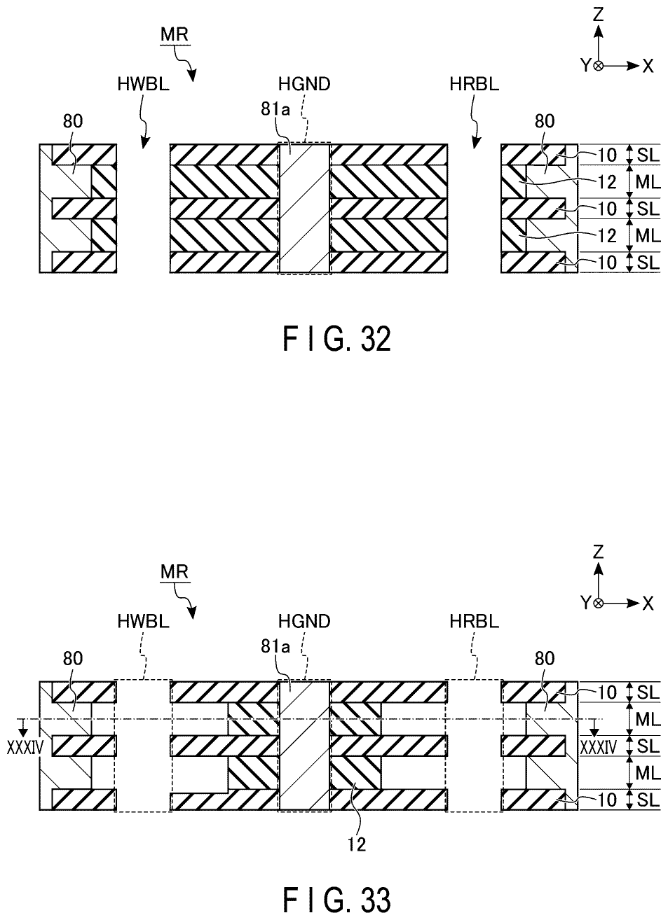

Next, as illustrated in FIG. 32, a sacrificial member 81a is embedded in the hole HGND. In the present step, for example, CVD is used to form the sacrificial member 81a. It should be noted that in the present step, the sacrificial member 81a may be formed so as to cover at least the insulating layer 10 and the sacrificial member 12 on the side surface of the hole HGND. The sacrificial member 81a is, for example, amorphous silicon (aSi).

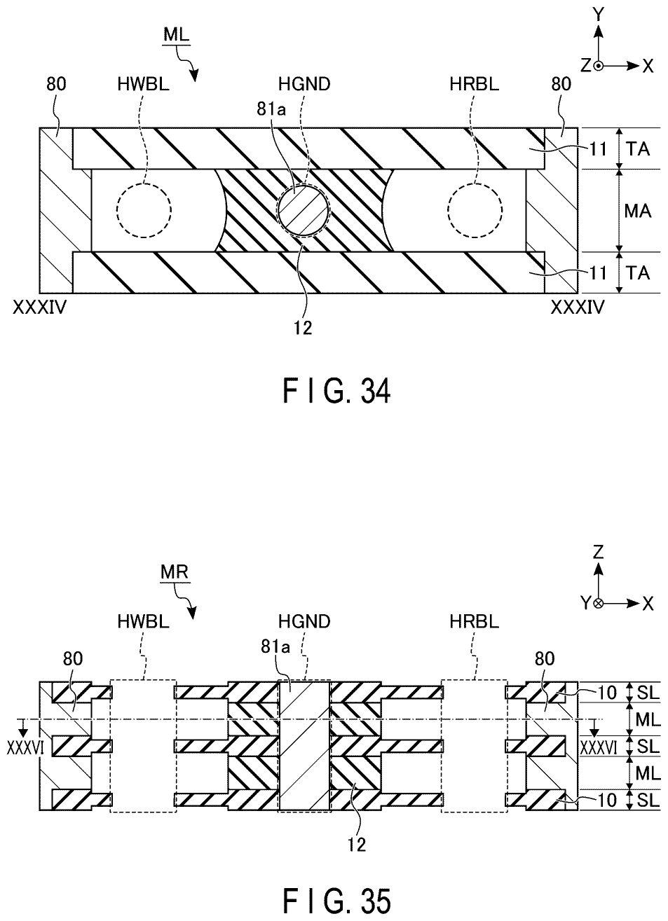

Next, as illustrated in FIG. 33, a recessed portion is formed by selectively removing the sacrificial member 12 of each memory layer ML through the holes HWBL and HRBL. In the present step, for example, wet etching processing is used to form the recessed portion. The recessed portion formed corresponding to the hole HWBL corresponds to a place where the write transistor WT is formed. In the present step, the recessed portion formed corresponding to the hole HRBL corresponds to a place where the read transistor RT2 is formed. A part of the sacrificial member 80 is exposed in the recessed portion of each of the holes HWBL and HRBL. FIG. 34 corresponds to a cross-section taken along line XXXIV-XXXIV in FIG. 33. As illustrated in FIG. 34, by the present step, in the XY cross-section, the sacrificial member 12 of each memory area MA is processed into an arc shape along a circle centered on the center position of the hole HWBL on one side (hole HWBL side) in the X direction, and processed into an arc shape along a circle centered on the center position of the hole HRBL on the other side (hole HRBL side) in the X direction.

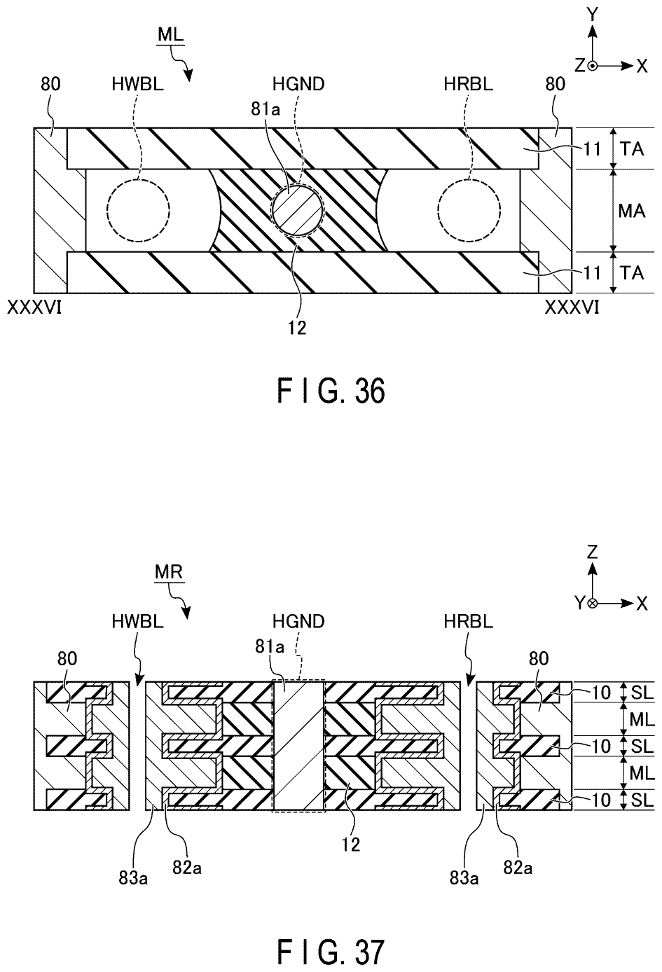

Next, as illustrated in FIG. 35, isotropic etching processing is performed through the holes HWBL and HRBL, and the insulating layer 10 of each separation layer SL is recessed. Accordingly, in each memory layer ML, each of the recessed portion of the hole HWBL and the recessed portion of the hole HRBL is enlarged in the Z direction. In the present step, in each of the holes HWBL and HRBL, the recessed portion enlarged in the Z direction is processed so as not to be connected between the two adjacent memory layers ML. In the present step, for example, wet etching processing is used. FIG. 36 corresponds to a cross-section taken along line XXXVI-XXXVI in FIG. 35. As illustrated in FIG. 36, in the present step, the diameter of each of holes HWBL and HRBL can be enlarged by recessing the insulating layer 10.

Next, as illustrated in FIG. 37, the conductive film 82a and the sacrificial member 83a are sequentially formed so that the recessed portion of each of the holes HWBL and HRBL is filled. The conductive film 82a of each of the holes HWBL and HRBL is in contact with each of the sacrificial members 80 and 12 in the memory layer ML. In addition, the conductive film 82a covers the upper surface, the lower surface, both side surfaces in the X direction, and both side surfaces in the Y direction of the insulating layer 10 in each of the holes HWBL and HRBL. In the present step, the sacrificial member 83a may be formed so as to embed each of the holes HWBL and HRBL. Each of the conductive film 82a and the sacrificial member 83a is formed by, for example, CVD or the like. The conductive film 82a is, for example, titanium nitride (TiN). The sacrificial member 83a is, for example, amorphous silicon (aSi).

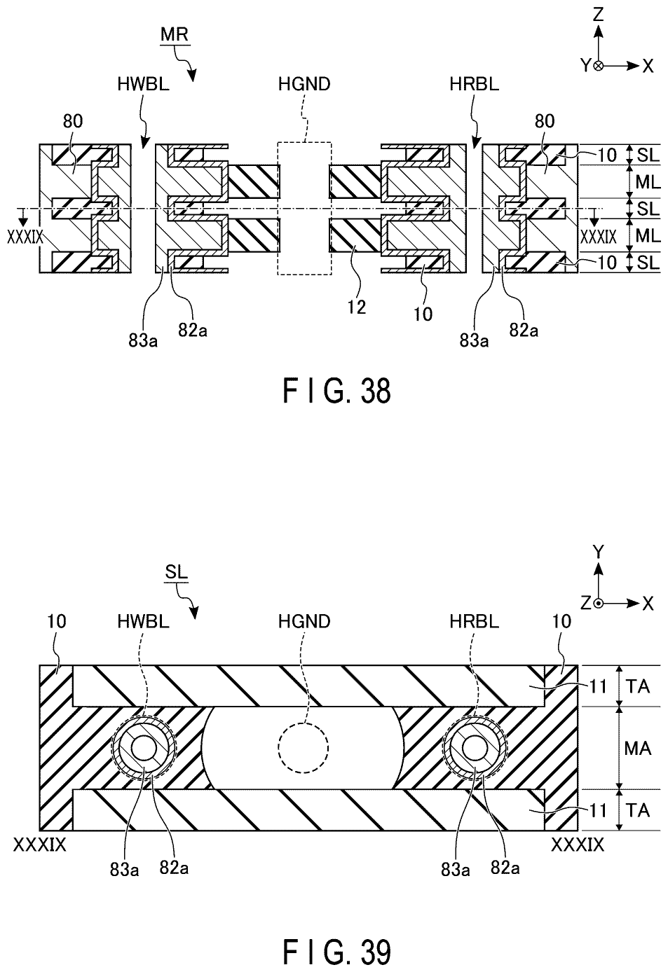

Next, as illustrated in FIG. 38, a part of the insulating layer 10 of each separation layer SL is selectively removed through the hole HGND. In the present step, for example, wet etching processing is used. FIG. 39 corresponds to a cross-section taken along line XXXIX-XXXIX in FIG. 38. As illustrated in FIG. 39, by the present step, in the insulating layer 10 of each separation layer SL, the portion provided on the hole HGND side is processed into an arc shape along a circle centered on the center position of the hole HGND in the XY cross-section.

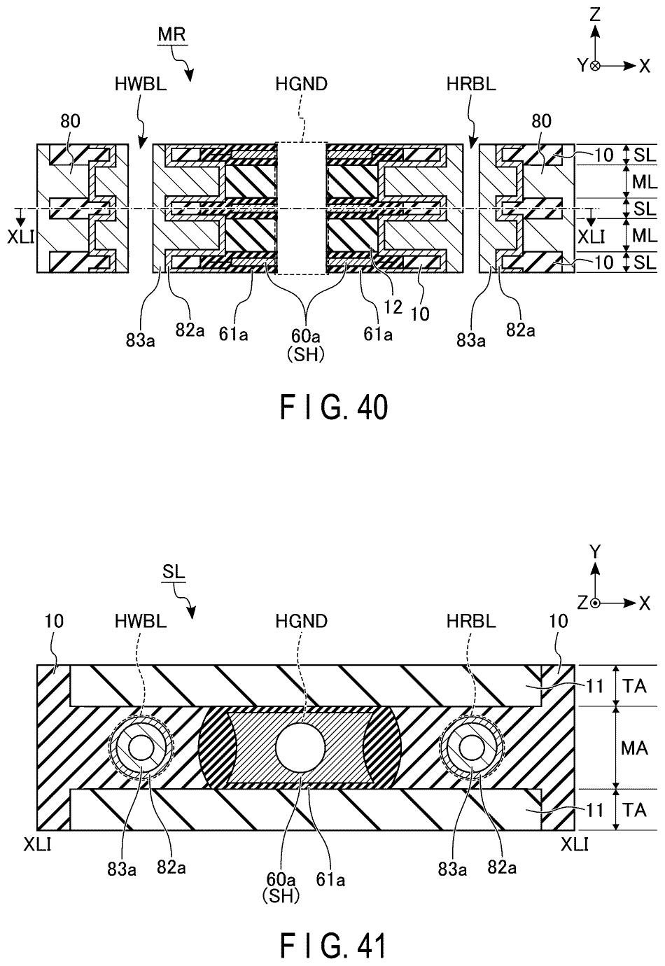

Next, as illustrated in FIG. 40, (1) an insulating film corresponding to the insulating layer 61a and a conductive film corresponding to the conductive layer 60a are formed, and (2) the insulating film and the conductive film provided on the side surface portion of the hole HGND are removed. In the present step, the insulating film corresponding to the insulating layer 61a is formed so that a portion sandwiched in the Z direction by the conductive film 82a is filled. Accordingly, a structure corresponding to the shield electrode SH is formed. By the present step, the side surface of the sacrificial member 12 of each memory layer ML is exposed in the hole HGND. In the present step, for example, CVD is used to form the insulating film and the conductive film. FIG. 41 corresponds to a cross-section taken along line XLI-XLI in FIG. 40. As illustrated in FIG. 41, in the insulating layer 61a, a portion sandwiched in the Z direction by the conductive film 82a is formed in a convex lens shape in the XY cross-section. Therefore, the conductive layer 60a is formed in a constricted shape along the insulating layer 61a in the separation layer SL.

Thereafter, processing similar to the processing described in the first embodiment with reference to FIGS. 20 to 24 is executed, and structures corresponding to the write bit line WBL, the ground line GND, the read bit line RBL, the write transistor WT, and the read transistors RT1 and RT2 are formed. Then, the sacrificial member 80 is removed, and a configuration corresponding to the write word line WWL and the read word line RWL is formed. As a result, the structure of the memory cell array 110 illustrated in FIGS. 27 to 29 is completed.

### <2-3> Advantageous Effects of Second Embodiment

In the memory device 100 according to the second embodiment, the insulating layer 10 of the separation layer SL is recessed by etching through the holes HWBL and HRBL. Then, a shield electrode SH is formed by self-alignment using the difference in thickness of the cavity. Specifically, a conductive layer 51a corresponding to the storage node SN and a conductive layer 60a corresponding to the shield electrode SH are formed by self-alignment.

By forming the conductive layer 51a and the conductive layer 60a by self-alignment, the shape of the shield electrode SH (conductive layer 60a) matches that of the conductive layer 50a connected to the write word line WWL. In other words, in the method for manufacturing the memory device 100 according to the second embodiment, the shield electrode SH and the write word line WWL can be formed without overlapping each other in the Z direction. As a result, an increase in parasitic capacitance between the shield electrode SH and the write word line WWL can be suppressed.

Similarly, by forming the conductive layer 52a and the conductive layer 60a by self-alignment, the shape of the shield electrode SH (conductive layer 60a) matches that of the conductive layer 52a connected to the read word line RWL. That is, in the memory device 100 according to the second embodiment, the shield electrode SH and the read word line RWL can be formed without overlapping each other in the Z direction. As a result, an increase in parasitic capacitance between the shield electrode SH and the read word line RWL can be suppressed.

As described above, the memory device 100 according to the second embodiment can suppress an overlap between the shield electrode SH and other electrodes and suppress an increase in parasitic capacitance. In addition, since the conductive layers 50a, 51a, 52a, and 60a are formed by self-alignment, it is possible to shrink a region that does not function as a channel in the memory cell MC. As a result, the gate electrode, the shield electrode SH, and the storage node SN of the write transistor WT are efficiently arranged, and the area of the memory cell MC can be reduced. Therefore, the memory device 100 according to the second embodiment can reduce the size of the memory cell array 110 and suppress the manufacturing cost of the memory device 100.

### <3> THIRD EMBODIMENT

In the memory device 100 according to the third embodiment, in plan view, one side in the X direction of the shield electrode SH is provided in a concave lens shape (arc shape), and the other side in the X direction of the shield electrode SH is provided in a convex lens shape (arc shape). In the following, details of the memory device 100 according to the third embodiment will be described mainly on the differences from the first and second embodiments.

### <3-1> Configuration

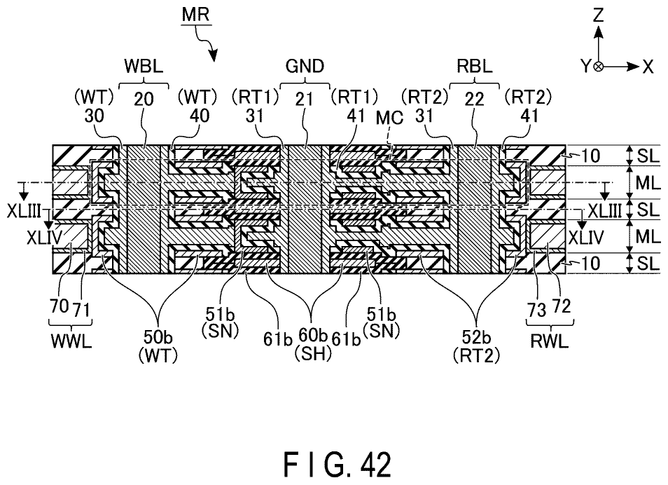

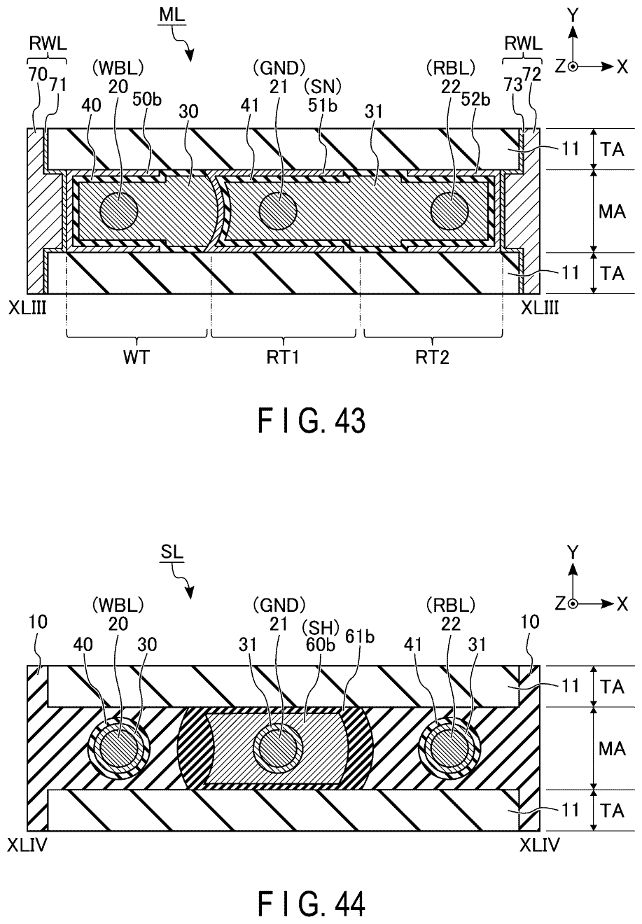

First, a configuration of a memory device 100 according to a third embodiment will be described with reference to FIGS. 42 to 44. Each of FIGS. 42 to 44 is a cross-sectional view illustrating an example of a structure of a memory cell array 110 included in the memory device 100 according to the third embodiment. FIG. 42 corresponds to the XZ cross-section of the memory cell array 110 provided in the memory region MR in the third embodiment, and extracts and illustrates a region including two memory cells MC adjacent in the Z direction. FIG. 43 corresponds to a cross-section taken along line XLIII-XLIII in FIG. 42. FIG. 44 corresponds to a cross-section taken along line XLIV-XLIV in FIG. 42.

The memory device 100 according to the third embodiment has the same configuration as the memory device 100 according to the first embodiment. On the other hand, in the memory device 100 according to the third embodiment, the shapes of the conductive layers 50, 51, and 60 and the insulating layer 61 are mainly different from those of the memory device 100 according to the first embodiment. Hereinafter, the conductive layers 50, 51, and 60, and the insulating layer 61 included in the memory device 100 according to the third embodiment are referred to as conductive layers 50b, 51b, and 60b, and an insulating layer 61b, respectively.

As illustrated in FIG. 42, in each memory layer ML, the conductive layer 50b and the conductive layer 52b have shapes protruding into the separation layer SL described in the first embodiment. Specifically, the width in the Z direction between the upper end and the lower end of the conductive layer 50b is wider than the width in the Z direction of the write word line WWL (conductive layers 70 and 71). The width in the Z direction between the upper end and the lower end of the conductive layer 52b is wider than the width in the Z direction of the read word line RWL (conductive layers 72 and 73). It should be noted that the width in the Z direction between the upper end and the lower end of the conductive layer 50b is, for example, substantially equal to the width in the Z direction between the upper end and the lower end of the conductive layer 52b.

Therefore, in the insulating layer 10, the thickness in the Z direction of a portion sandwiched between two conductive layers 50b adjacent in the Z direction is thinner than the thickness in the Z direction of a portion sandwiched between two write word lines WWL adjacent in the Z direction. Similarly, in the insulating layer 10, the thickness in the Z direction of a portion sandwiched between two conductive layers 52b adjacent in the Z direction is thinner than the thickness in the Z direction of a portion sandwiched between two read word lines RWL adjacent in the Z direction. In addition, the interval between the upper end and the lower end in the Z direction of the conductive layer 51b is narrower than each of the interval between the upper end and the lower end in the Z direction of the conductive layer 50b and the interval between the upper end and the lower end in the Z direction of the conductive layer 52b.

Then, the insulating layer 61b is provided to be closed at each of a portion sandwiched between two conductive layers 50b adjacent in the Z direction and a portion sandwiched between two conductive layers 52b adjacent in the Z direction. Therefore, the conductive layer 60b is disposed away from each of the conductive layers 50b and 52b by an amount corresponding to the closing of the insulating layer 61b in plan view. Accordingly, the conductive layer 60b is not included in each of a portion sandwiched between two conductive layers 50b adjacent in the Z direction and a portion sandwiched between two conductive layers 52b adjacent in the Z direction.

As illustrated in FIG. 43, in the XY cross-section, a side surface portion on the other side (conductive layer 72) in the X direction of the semiconductor layer 30 of the third embodiment is formed in an arc shape along a circle centered on the center position of the conductive member 20 (via wiring line). Although not illustrated, in the XY cross-section, a side surface portion on the other side in the X direction of the conductive layer 50b is formed in an arc shape along a circle centered on the center position of the conductive member 20 (via wiring line). In the XY cross-section, a side surface portion on one side (conductive layer 70 side) in the X direction of the semiconductor layer 31 of the third embodiment is formed in an arc shape along a circle centered on the center position of the conductive member 20 (via wiring line). Although not illustrated, in the XY cross-section, a side surface portion on one side in the X direction of the conductive layer 51b is formed in an arc shape along a circle centered on the center position of the conductive member 20 (via wiring line). Although not illustrated, in the XY cross-section, a side surface portion on the other side in the X direction of the conductive layer 51b is formed in an arc shape along a circle centered on the center position of the conductive member 21 (via wiring line). Although not illustrated, in the XY cross-section, a side surface portion on one side in the X direction of the conductive layer 52b is formed in an arc shape along a circle centered on the center position of the conductive member 21 (via wiring line).

As illustrated in FIG. 44, in the XY cross-section, a side surface portion on one side in the X direction of the conductive layer 60b is formed in an arc shape along a circle centered on the center position of the conductive member 20 (via wiring line). In the XY cross-section, a side surface portion on the other side in the X direction of the conductive layer 60b is formed in an arc shape along a circle centered on the center position of the conductive member 21 (via wiring line). In the XY cross-section, each of the side surface portion on one side in the X direction of the insulating layer 61b and the side surface portion on the other side in the X direction of the insulating layer 61b is formed in an arc shape along a circle centered on the center position of the conductive member 21 (via wiring line). In addition, in the XY cross-section, the shape of the portion on one side in the X direction of the insulating layer 61b is a convex lens shape. The width in the Y direction between both end portions in the Y direction of the insulating layer 61b is substantially equal to the width in the Y direction of the memory area MA. The width in the X direction between both end portions in the X direction of the insulating layer 61b is larger than the width in the Y direction of the memory area MA. In the insulating layer 61b, the width in the X direction of a portion sandwiched between the conductive layer 60b and the insulating layer 10 is narrower than the width in the X direction of a portion sandwiched between the conductive layer 60b and the insulating member 11.

Other configurations of the memory device 100 according to the third embodiment are similar to those of the memory device 100 according to the first embodiment.

### <3-2> Manufacturing Method

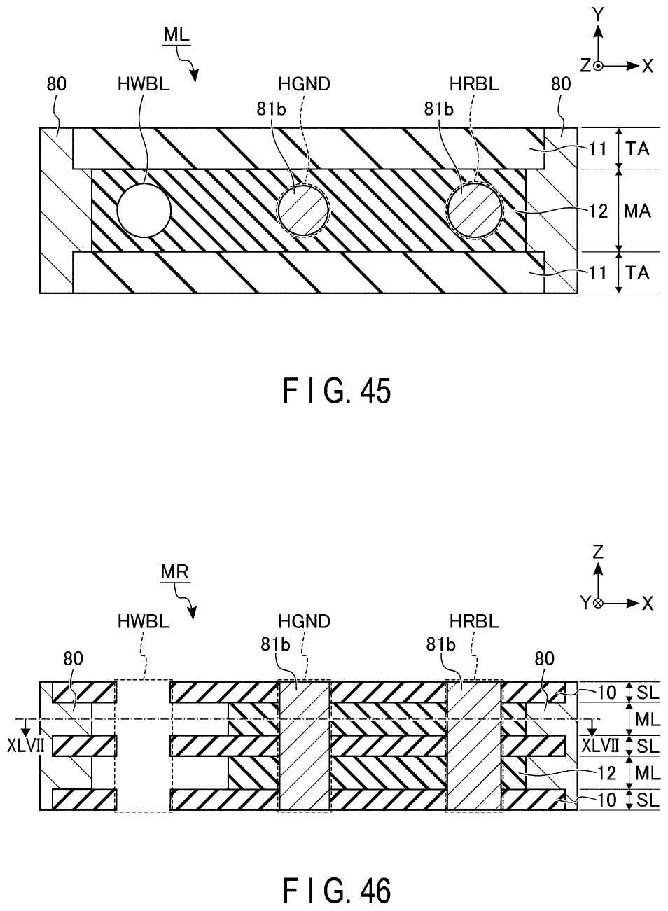

Next, as a method for manufacturing the memory device 100 according to the third embodiment, a process of forming the memory cell array 110 will be described with reference to FIGS. 45 to 62. Each of FIGS. 45 to 62 is a cross-sectional view illustrating an example of a structure in a step for manufacturing the memory device 100 according to the third embodiment. Each of FIGS. 45 to 62 illustrates the same region as any one of the memory region MR illustrated in FIG. 42, the memory layer ML illustrated in FIG. 43, or the separation layer SL illustrated in FIG. 44. In the method for manufacturing the memory device 100 according to the third embodiment, first, the processing described with reference to FIGS. 7 to 10 in the first embodiment is executed.

In the method for manufacturing the memory device 100 according to the third embodiment, first, the processing described with reference to FIGS. 7 to 10 in the first embodiment is executed, and the structure illustrated in FIG. 10 is formed. Then, the processing described with reference to FIGS. 30 and 31 in the second embodiment is executed, and the structure illustrated in FIGS. 30 and 31 is formed.

Next, as illustrated in FIG. 45, a sacrificial member 81b is embedded in the holes HGND and HRBL. In the present step, for example, CVD is used to form the sacrificial member 81b. It should be noted that in the present step, the sacrificial member 81b may to be formed so as to cover at least the insulating layer 10 and the sacrificial member 12 on the side surface of the holes HGND and HRBL. The sacrificial member 81b is, for example, amorphous silicon (aSi).

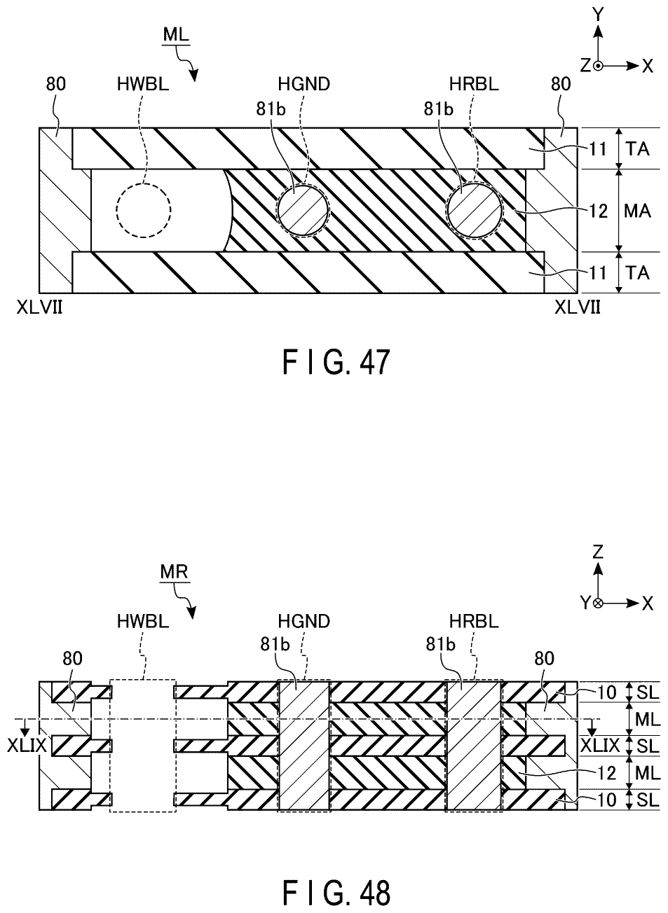

Next, as illustrated in FIG. 46, a recessed portion is formed by selectively removing the sacrificial member 12 of each memory layer ML through the hole HWBL. In the present step, for example, wet etching processing is used to form the recessed portion. The recessed portion formed corresponding to the hole HWBL corresponds to a place where the write transistor WT is formed. A part of the sacrificial member 80 is exposed in the recessed portion of the hole HWBL. FIG. 47 is a cross-sectional view taken along line XLVII-XLVII in FIG. 46. As illustrated in FIG. 47, by the present step, the sacrificial member 12 of each memory area MA is processed into an arc shape along a circle centered on the center position of the hole HWBL on one side (hole HWBL side) in the X direction in the XY cross-section.

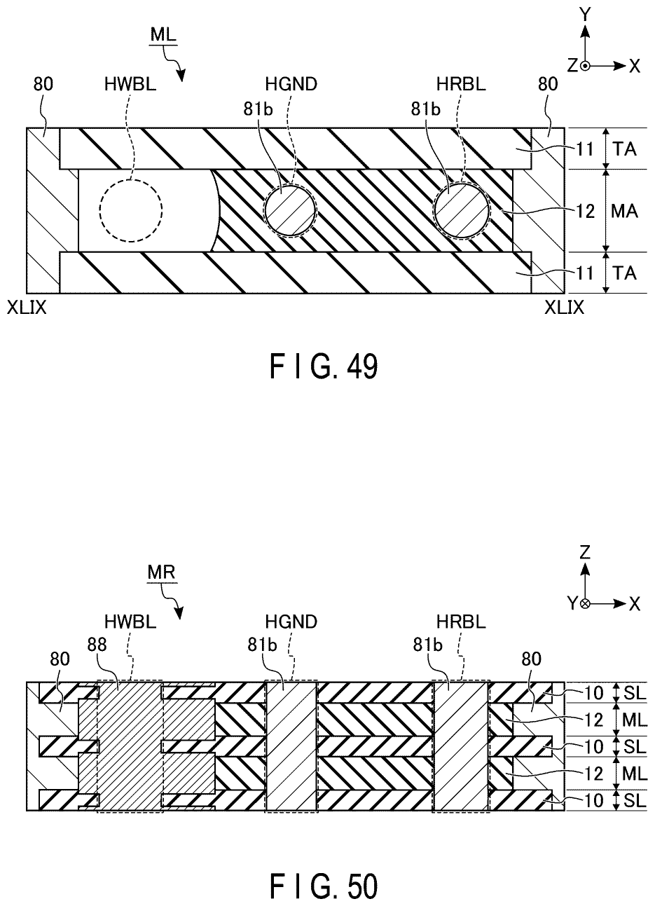

Next, as illustrated in FIG. 48, isotropic etching processing is performed through the hole HWBL, and the insulating layer 10 of each separation layer SL is recessed. Accordingly, in each memory layer ML, the recessed portion of the hole HWBL is enlarged in the Z direction. In the present step, in the hole HWBL, the recessed portion enlarged in the Z direction is processed so as not to be connected between the two adjacent memory layers ML. In the present step, for example, wet etching processing is used. FIG. 49 corresponds to a cross-section taken along line XLIX-XLIX in FIG. 48. As illustrated in FIG. 49, in the present step, the diameter of the hole HWBL can be enlarged by recessing the insulating layer 10.

Next, as illustrated in FIG. 50, a sacrificial member 88 is embedded in the hole HWBL. In the present step, for example, CVD is used to form the sacrificial member 88. It should be noted that in the present step, the sacrificial member 88 may be formed so as to cover at least the insulating layer 10 on the side surface of the hole HWBL, the sacrificial member 12, and the sacrificial member 80. The material of the sacrificial member 88 is different from that of the sacrificial member 81b. The sacrificial member 88 is, for example, amorphous carbon (aC).

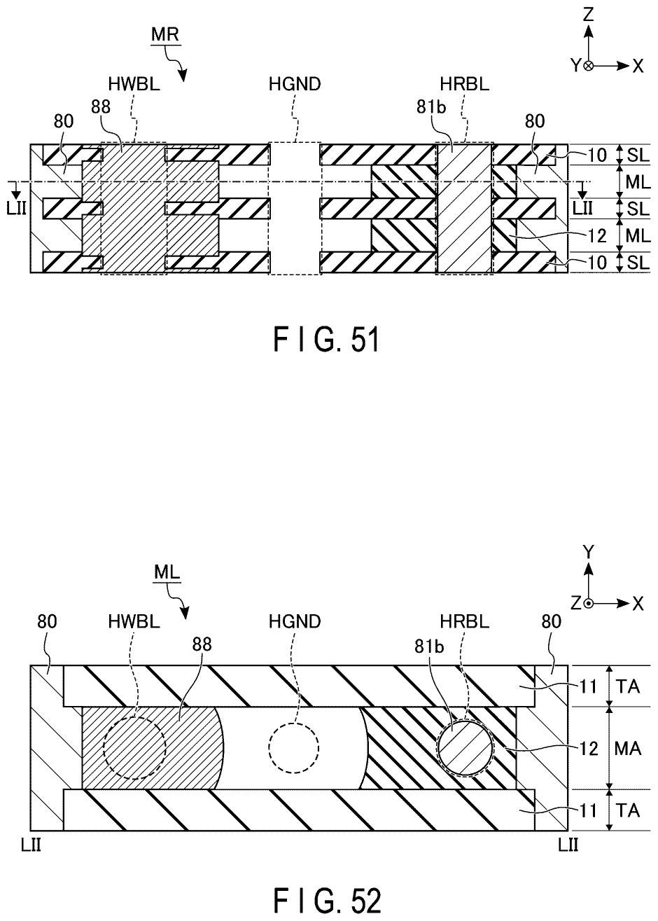

Next, as illustrated in FIG. 51, (1) the sacrificial member 81b in the hole HGND is removed, and (2) a recessed portion is formed by selectively removing a part of the sacrificial member 12 of each memory layer ML through the hole HGND. Accordingly, the side surface of the sacrificial member 88 is exposed in the portion corresponding to each memory layer ML in the hole HGND. FIG. 52 corresponds to a cross-section taken along line LII-LII in FIG. 50. As illustrated in FIG. 52, the sacrificial member 12 is substantially completely removed on one side in the X direction of the recessed portion of the hole HGND. On the other hand, on the other end side in the X direction of the recessed portion of the hole HGND, the sacrificial member 12 is processed into an arc shape centered on the center position of the hole HGND in the XY cross-section.

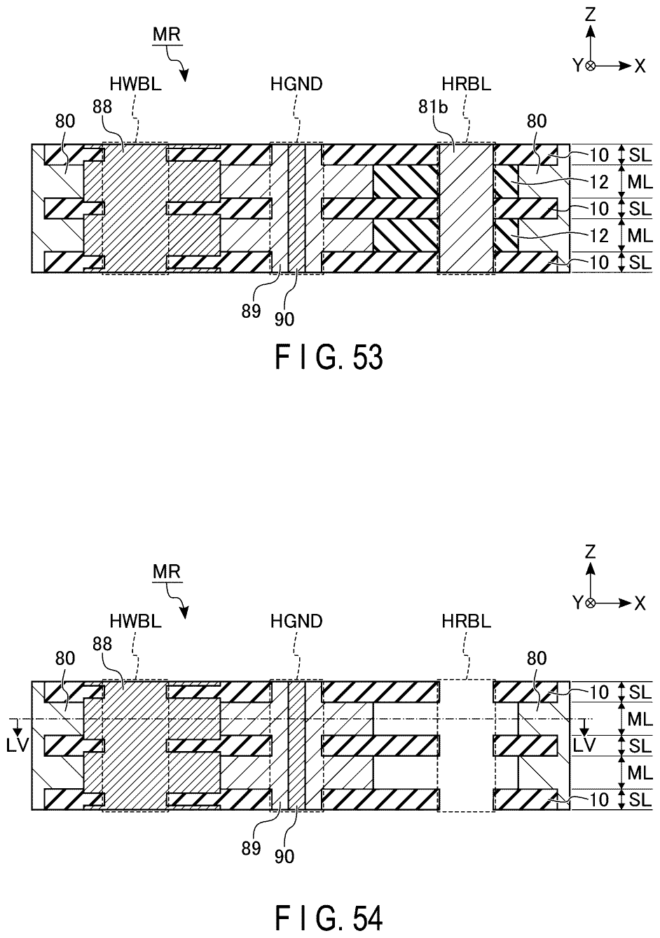

Next, as illustrated in FIG. 53, (1) a sacrificial member 89 is formed so as to fill the recessed portion of the hole HGND, and (2) the hole HGND is embedded by a sacrificial member 90. Each of the sacrificial members 89 and 90 is formed by, for example, CVD or the like. The sacrificial members 89 and 90 are made of different materials. The sacrificial member 89 is, for example, amorphous silicon (aSi). The sacrificial member 90 is, for example, amorphous carbon (aC).

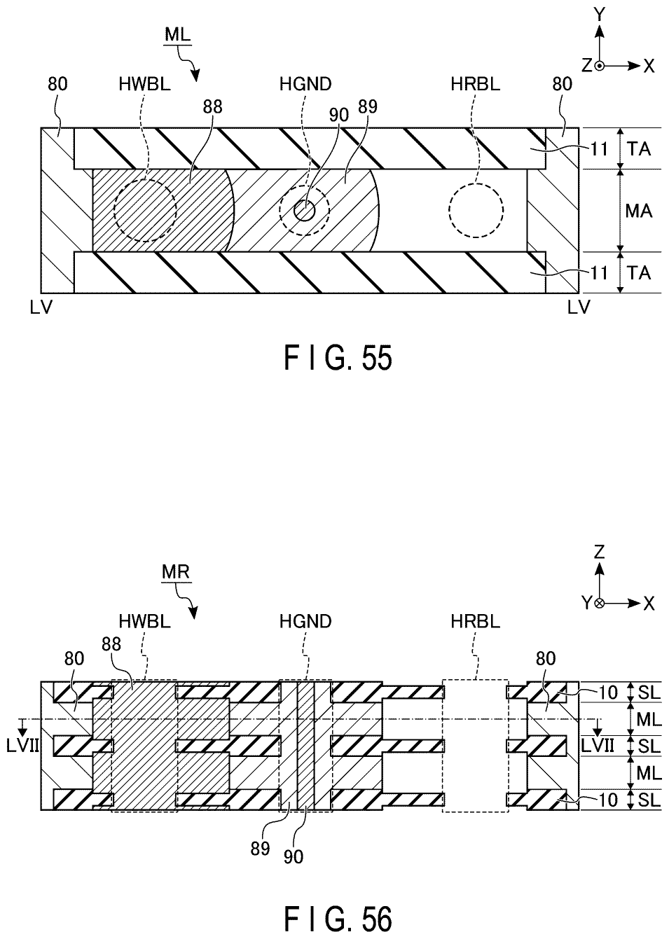

Next, as illustrated in FIG. 54, (1) the sacrificial member 81b in the hole HRBL is removed, and (2) a recessed portion is formed by selectively removing the sacrificial member 12 of each memory layer ML through the hole HRBL. Accordingly, the side surface of each of the sacrificial members 80 and 89 is exposed in the portion corresponding to each memory layer ML in the hole HRBL. FIG. 55 corresponds to a cross-section taken along line LV-LV in FIG. 54. As illustrated in FIG. 55, in the XY cross-section, on one side in the X direction of the recessed portion of the hole HRBL, the arc-shaped sacrificial member 89 centered on the center position of the hole HGND is exposed. On the other hand, in the XY cross-section, on the other side in the X direction of the recessed portion of the hole HRBL, the linear sacrificial member 80 is exposed.

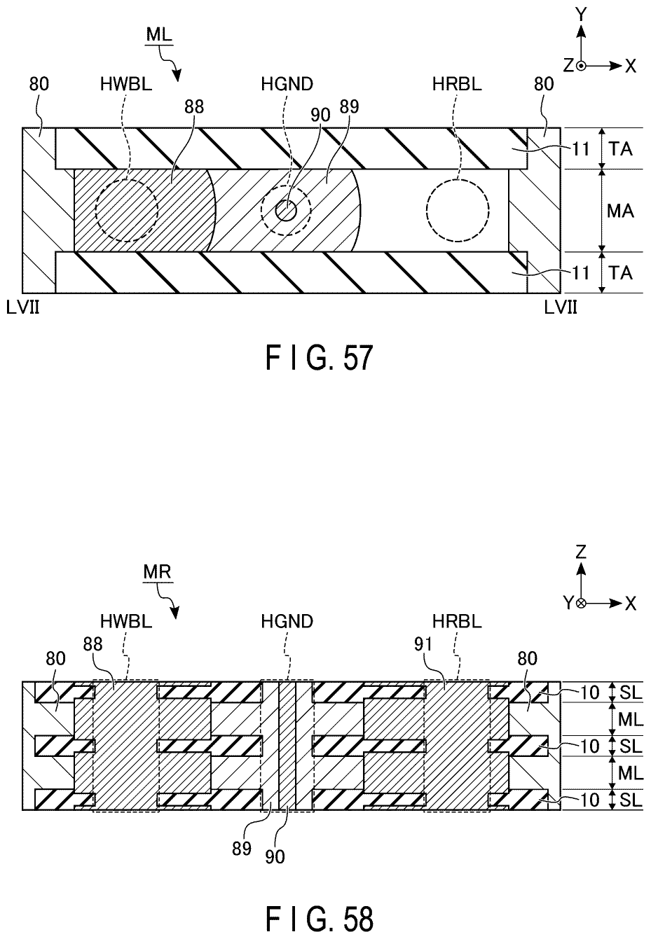

Next, as illustrated in FIG. 56, isotropic etching processing is performed through the hole HRBL, and the insulating layer 10 of each separation layer SL is recessed. Accordingly, in each memory layer ML, the recessed portion of the hole HRBL is enlarged in the Z direction. In the present step, in the hole HRBL, the recessed portion enlarged in the Z direction is processed so as not to be connected between the two adjacent memory layers ML. In the present step, for example, wet etching processing is used. FIG. 57 corresponds to a cross-section taken along line XVII-XVII in FIG. 56. As illustrated in FIG. 57, in the present step, the diameter of the hole HRBL can be enlarged by recessing the insulating layer 10.

Next, as illustrated in FIG. 58, a sacrificial member 91 is embedded in the hole HRBL. In the present step, for example, CVD is used to form the sacrificial member 91. It should be noted that in the present step, the sacrificial member 91 may be formed so as to cover at least the insulating layer 10 on the side surface of the hole HRBL and the sacrificial members 80 and 89. The material of the sacrificial member 91 is different from that of each of the sacrificial members 80 and 89. The sacrificial member 91 is, for example, amorphous carbon (aC).

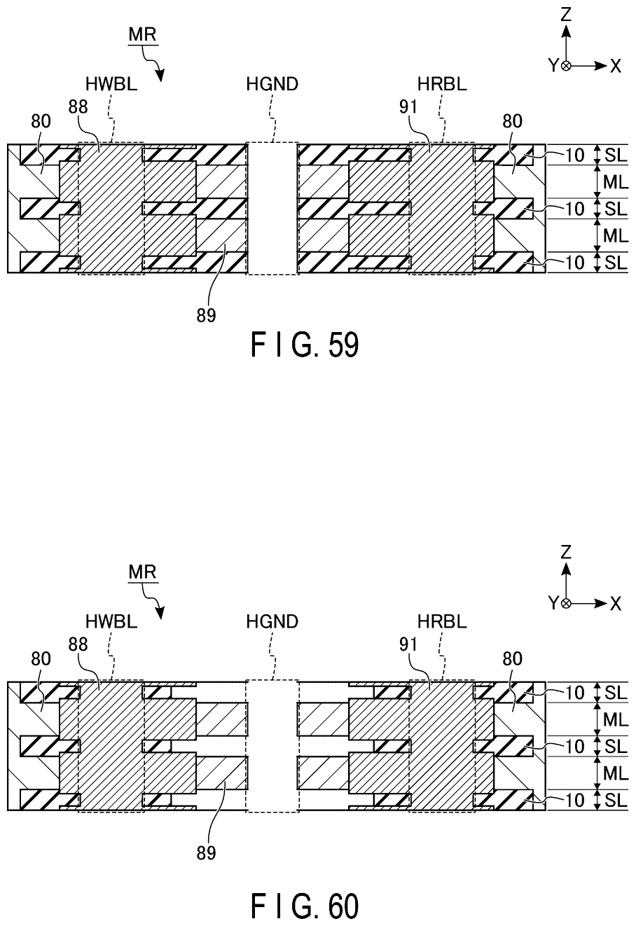

Next, as illustrated in FIG. 59, (1) the sacrificial member 90 in the hole HGND is selectively removed, and (2) the sacrificial member 89 in the hole HGND is removed so that the sacrificial member 89 in the recessed portion of the hole HGND remains. In the present step, for example, wet etching processing is used. Accordingly, the sacrificial member 89 formed in the recessed portion of the hole HGND is separated between the memory layers ML. Then, in the hole HGND, the side surface of the insulating layer 10 of each separation layer SL is exposed.

Next, as illustrated in FIG. 60, a part of the insulating layer 10 of each separation layer SL is selectively removed through the hole HGND. In the present step, for example, wet etching processing is used. By the present step, in the insulating layer 10 of each separation layer SL, the portion provided on the hole HGND side is processed into an arc shape along a circle centered on the center position of the hole HGND in the XY cross-section (not illustrated).

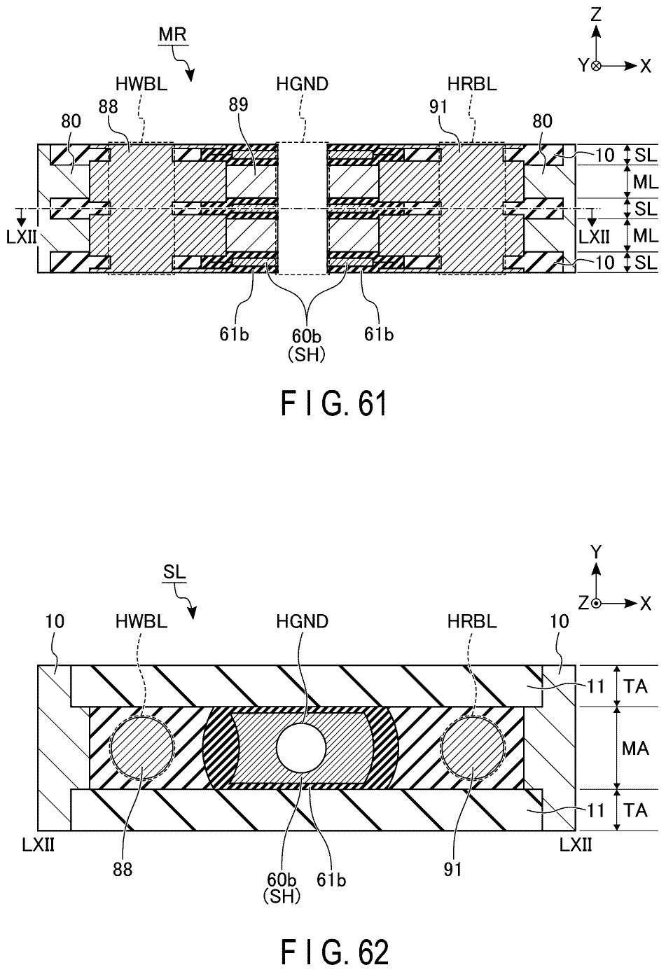

Next, as illustrated in FIG. 61, (1) an insulating film corresponding to the insulating layer 61b and a conductive film corresponding to the conductive layer 60b are formed, and (2) the insulating film and the conductive film provided on the side surface portion of the hole HGND are removed. In the present step, the insulating film corresponding to the insulating layer 61b is formed so that a portion sandwiched in the Z direction by the sacrificial member 88 or 91 is filled. Accordingly, a structure corresponding to the shield electrode SH is formed. By the present step, the side surface of the sacrificial member 89 of each memory layer ML is exposed in the hole HGND. In the present step, for example, CVD is used to form the insulating film and the conductive film. FIG. 62 corresponds to a cross-section taken along line LXII-LXII in FIG. 61. As illustrated in FIG. 62, in the insulating layer 61b, a portion sandwiched in the Z direction by the sacrificial member 88 is formed in a convex lens shape in the XY cross-section. In addition, in the insulating layer 61b, a portion sandwiched in the Z direction by the sacrificial member 91 is formed in an arch shape thicker than the film thickness of the insulating layer 61b formed in the present step in the XY cross-section.

Next, although not illustrated, the sacrificial member 88 is removed through the hole HWBL, and the sacrificial member 91 is removed through the hole HRBL. Then, as described in the second embodiment with reference to FIG. 37, the conductive film 82a and the sacrificial member 83a are sequentially formed so that the recessed portion of each of the holes HWBL and HRBL is filled. Thereafter, in the processing described with reference to FIGS. 20 to 24 in the first embodiment, processing similar to the case where the sacrificial member 84 is replaced with the sacrificial member 89 is executed, and structures corresponding to the write bit line WBL, the ground line GND, the read bit line RBL, the write transistor WT, and the read transistors RT1 and RT2 are formed. Then, the sacrificial member 80 is removed, and a configuration corresponding to the write word line WWL and the read word line RWL is formed. As a result, the structure of the memory cell array 110 illustrated in FIGS. 42 to 44 is completed.

### <3-3> Advantageous Effects of Third Embodiment

In the memory device 100 according to the third embodiment, as in the second embodiment, the insulating layer 10 of the separation layer SL is recessed by etching through the holes HWBL and HRBL. Then, a shield electrode SH is formed by self-alignment using the difference in thickness of the cavity. Specifically, a conductive layer 51b corresponding to the storage node SN and a conductive layer 60b corresponding to the shield electrode SH are formed by self-alignment.

Accordingly, as in the second embodiment, the memory device 100 according to the third embodiment can suppress an overlap between the shield electrode SH and other electrodes and suppress an increase in parasitic capacitance. In addition, since the conductive layers 50b, 51b, 52b, and 60b are formed by self-alignment, it is possible to shrink a region that does not function as a channel in the memory cell MC. As a result, the gate electrode, the shield electrode SH, and the storage node SN of the write transistor WT are efficiently arranged, and the area of the memory cell MC can be reduced. Therefore, the memory device 100 according to the third embodiment can reduce the size of the memory cell array 110 and suppress the manufacturing cost of the memory device 100.

### <3-4> Modification of Third Embodiment

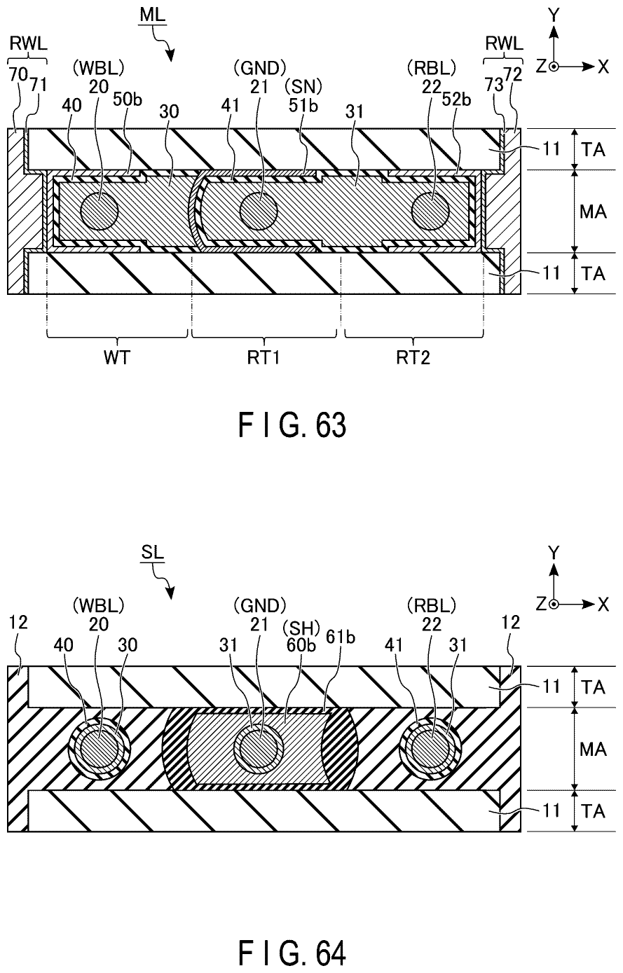

In the memory device 100 according to the third embodiment, the shape of the shield electrode SH may be a shape inverted in the X direction. In the following, a modification of the third embodiment will be described with reference to FIGS. 63 and 64. It should be noted that in the modification of the third embodiment, let the shape of the XY cross-section in the memory region MR of the memory cell array 110 be similar to that in FIG. 27.

Each of FIGS. 63 and 64 is a cross-sectional view illustrating an example of a structure of the memory cell array 110 included in the memory device 100 according to the modification of the third embodiment. FIG. 63 illustrates a cross-section at the same position as the cross-section taken along line XXVIII-XXVIII in FIG. 27. FIG. 64 illustrates a cross-section at the same position as the cross-section taken along line XXIX-XXIX in FIG. 27.

As illustrated in FIG. 63, in the XY cross-section, a side surface portion on the other side (conductive layer 72 side) in the X direction of the semiconductor layer 30 of the modification of the third embodiment is formed in an arc shape along a circle centered on the center position of the conductive member 21 (via wiring line). Although not illustrated, in the XY cross-section, a side surface portion on the other side in the X direction of the conductive layer 50b is formed in an arc shape along a circle centered on the center position of the conductive member 21 (via wiring line). In the XY cross-section, a side surface portion on one side (conductive layer 70 side) in the X direction of the semiconductor layer 31 of the modification of the third embodiment is formed in an arc shape along a circle centered on the center position of the conductive member 21 (via wiring line). Although not illustrated, in the XY cross-section, a side surface portion on one side in the X direction of the conductive layer 51b is formed in an arc shape along a circle centered on the center position of the conductive member 21 (via wiring line). Although not illustrated, in the XY cross-section, a side surface portion on the other side in the X direction of the conductive layer 51b is formed in an arc shape along a circle centered on the center position of the conductive member 22 (via wiring line). Although not illustrated, in the XY cross-section, a side surface portion on one side in the X direction of the conductive layer 52b is formed in an arc shape along a circle centered on the center position of the conductive member 22 (via wiring line).

As illustrated in FIG. 64, in the XY cross-section, a side surface portion on one side in the X direction of the conductive layer 60b of the modification of the third embodiment is formed in an arc shape along a circle centered on the center position of the conductive member 21 (via wiring line). In the XY cross-section, a side surface portion on the other side in the X direction of the conductive layer 60b of the modification of the third embodiment is formed in an arc shape along a circle centered on the center position of the conductive member 22 (via wiring line). In the XY cross-section, a side surface portion on one side in the X direction of the insulating layer 61b of the modification of the third embodiment is formed in an arc shape along a circle centered on the center position of the conductive member 21 (via wiring line). In the XY cross-section, a side surface portion on the other side in the X direction of the insulating layer 61b of the modification of the third embodiment is formed in an arc shape along a circle centered on the center position of the conductive member 21 (via wiring line). In addition, in the XY cross-section, the shape of the portion on the other side in the X direction of the insulating layer 61b of the modification of the third embodiment is a convex lens shape.

Other configurations of the memory device 100 according to the modification of the third embodiment are similar to those of the memory device 100 according to the third embodiment. The memory device 100 according to the modification of the third embodiment can obtain the same advantageous effects as those of the third embodiment.

### <4> FOURTH EMBODIMENT

In a memory device 100A according to a fourth embodiment, a shield electrode SH as in the first embodiment is combined with a DRAM including a memory cell having a 2 transistor 0 capacitor (2T0C) structure. In the following, details of the memory device 100A according to the fourth embodiment will be described mainly on the differences from the first to third embodiments.

### <4-1> Configuration

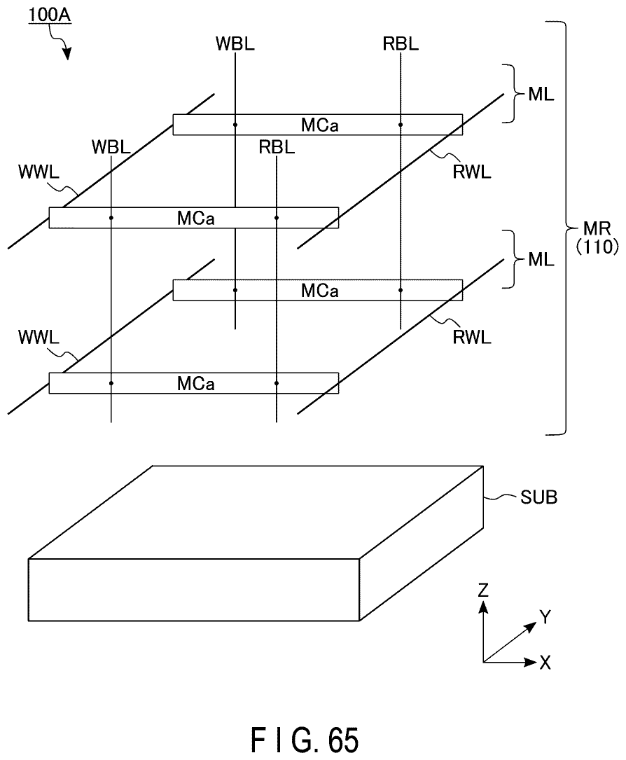

First, a configuration of the memory device 100A according to the fourth embodiment will be described with reference to FIGS. 65 to 69.

### <4-1-1> Structure of Memory Device 100A

FIG. 65 is a perspective view illustrating an example of a structure of the memory device 100A according to the fourth embodiment. As illustrated in FIG. 65, the memory device 100A has a configuration in which the memory cell MC is replaced with a memory cell MCa, and a plurality of ground lines GND are omitted, as compared with the memory device 100 of the first embodiment. Specifically, the memory region MR of the fourth embodiment includes a plurality of memory cells MCa, a plurality of write word lines WWL, and a plurality of read word lines RWL. Then, the memory region MR includes a plurality of memory layers ML arranged in the Z direction.

Each memory layer ML of the fourth embodiment includes a pair of write word line WWL and read word line RWL arranged in the X direction and a plurality of memory cells MCa arranged in the Y direction. In each memory layer ML of the fourth embodiment, each of the plurality of memory cells MCa is disposed between the pair of write word line WWL and read word line RWL, and is electrically connected to each of the pair of write word line WWL and read word line RWL.

In the memory region MR of the fourth embodiment, the pair of write bit line WBL and read bit line RBL is arranged in the X direction. In the memory region MR, a plurality of write bit lines WBL are arranged in the Y direction. In the memory region MR, a plurality of read bit lines RBL are arranged in the Y direction. The pair of write bit line WBL and read bit line RBL is electrically connected to one memory cell MCa, in each memory layer ML.

It should be noted that the structure of the memory device 100A according to the fourth embodiment is not limited to the structure illustrated in FIG. 65. In the memory region MR, each of the number of write word lines WWL arranged in the Z direction and the number of read word lines RWL arranged in the Z direction may be two or more. In addition, in the memory region MR, each of the number of write bit lines WBL arranged in the Y direction and the number of read bit lines RBL arranged in the Y direction may be two or more.

### <4-1-2> Circuit Configuration of Memory Cell

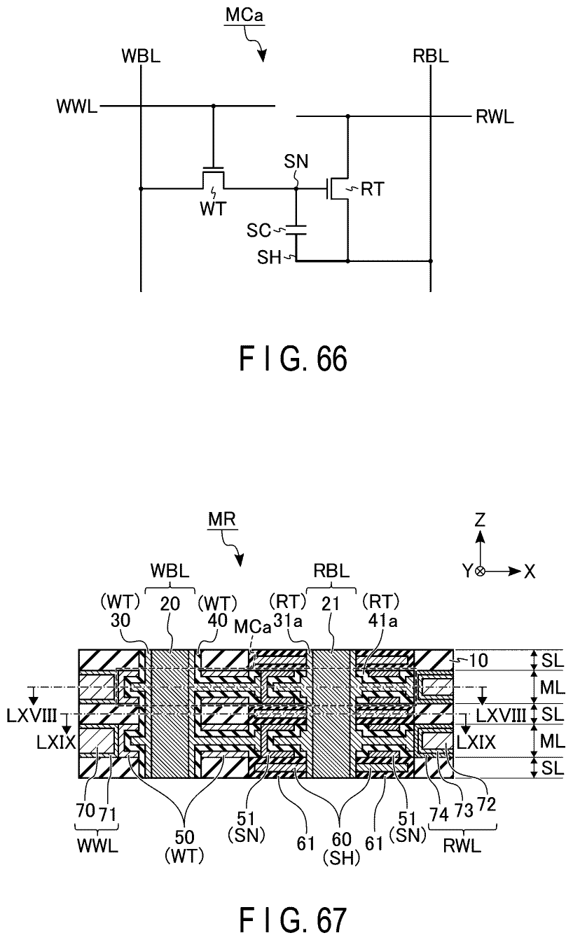

FIG. 66 is a circuit diagram illustrating an example of a circuit configuration of a memory cell MCa included in the memory device 100A according to the fourth embodiment. It should be noted that FIG. 66 illustrates one memory cell MCa, a pair of write word line WWL and read word line RWL, and a pair of write bit line WBL and read bit line RBL. As illustrated in FIG. 66, the memory cell MCa is configured to have a 2T0C structure. Specifically, the memory cell MCa includes, for example, a write transistor WT, a read transistor RT, and a storage node SN.

The configuration of the write transistor WT of the memory cell MCa is similar to that of the write transistor WT of the memory cell MC described in the first embodiment.

The read transistor RT is, for example, a field-effect NMOS transistor. The gate electrode of the read transistor RT is connected to the storage node SN. One electrode of the read transistor RT is connected to the read bit line RBL. The other electrode of the read transistor RT is connected to the read word line RWL. Each of the one electrode and the other electrode of the read transistor RT functions as a source electrode or a drain electrode according to the voltage supplied to the read transistor RT.

The storage node SN of the memory cell MCa has parasitic capacitance (<1 fF) similarly to that of the memory cell MC of the first embodiment. The memory cell MCa can store data according to the potential of the parasitic capacitance of the storage node SN, that is, the amount of charge accumulated in the storage node SN. The leakage current from the storage node SN is limited by the leakage current of the write transistor WT. Therefore, the memory device 100A can read the data of the memory cell MCa in a non-destructive manner by reading the current of the read transistor RT according to the potential of the storage node SN in the read operation.

In the memory device 100A according to the fourth embodiment, a shield electrode SH is provided in the vicinity of the memory cell MCa. The shield electrode SH is electrically connected to the read bit line RBL. The shield electrode SH is arranged to face the storage node SN, and suppresses interference between two memory cells MCa adjacent in the Z direction. In FIG. 66, the parasitic capacitance between the storage node SN and the shield electrode SH is illustrated as the parasitic capacitance SC. The detailed arrangement of the two memory cells MCa adjacent in the Z direction and the shield electrode SH will be described below.

### <4-1-3> Structure of Memory Cell Array 110

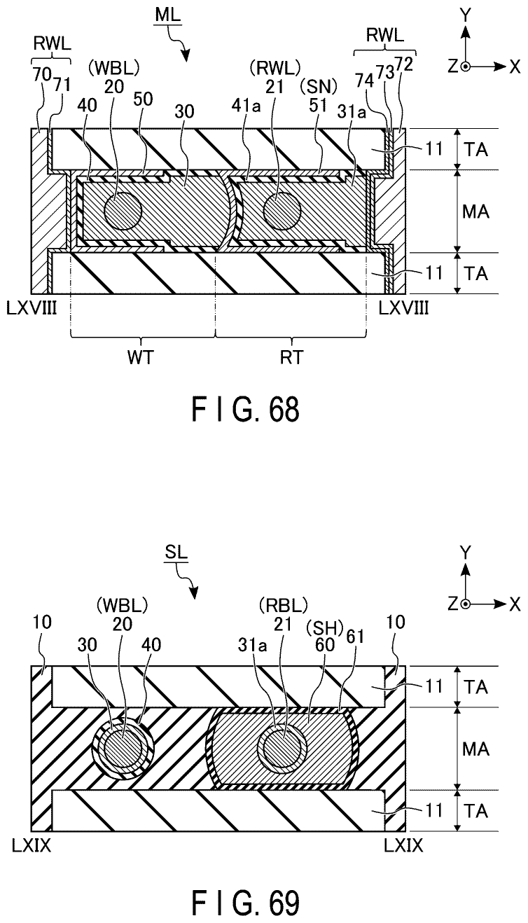

Each of FIGS. 67 to 69 is a cross-sectional view illustrating an example of a structure of a memory cell array 110 included in the memory device 100A according to the fourth embodiment. FIG. 67 corresponds to the XZ cross-section of the memory cell array 110 provided in the memory region MR in the fourth embodiment, and extracts and illustrates a region including two memory cells MCa adjacent in the Z direction. FIG. 68 corresponds to a cross-section taken along line LXVIII-LXVIII in FIG. 67. FIG. 69 corresponds to a cross-section taken along line LXIX-LXIX in FIG. 67.

The memory device 100A according to the fourth embodiment includes a configuration in which the configuration related to the read transistor RT2 is omitted from the memory device 100 according to the first embodiment. Then, in the memory device 100A according to the fourth embodiment, a configuration corresponding to the read transistor RT1 of the first embodiment is used in the read transistor RT. Hereinafter, the semiconductor layer 31 and the insulating layer 41 included in the memory device 100A according to the fourth embodiment are referred to as a semiconductor layer 31a and an insulating layer 41a, respectively.

As illustrated in FIG. 67, a conductive member 21 of the fourth embodiment has the same structure as that of the first embodiment and functions as a read bit line RBL. The semiconductor layer 31a has a cylindrical first portion extending in the Z direction and provided on the side surface of the conductive member 21 and a second portion extending in the X direction in the memory layer ML. The insulating layer 40a includes a cylindrical first portion extending in the Z direction and provided on a side surface of the first portion of the semiconductor layer 30a, and a second portion provided on an upper surface, a lower surface, both side surfaces in the Y direction, and a side surface on one side (conductive layer 70 side) in the X direction of the second portion of the semiconductor layer 30a in the memory layer ML. The read word line RWL of the fourth embodiment further includes a conductive layer 74. The conductive layer 74 is provided, for example, on an upper surface, a lower surface, both side surfaces in the Y direction, and a side surface on one side in the X direction of the conductive layer 73. In each memory layer ML, the second portion of the semiconductor layer 31a is connected to a read word line RWL (for example, the conductive layer 74) provided in the same layer in each memory layer ML. Then, the semiconductor layer 31a is electrically connected to the conductive layer 72 with the conductive layers 74 and 73 interposed therebetween.

As illustrated in FIG. 68, in the XY cross-section, a side surface portion on one side in the X direction of the semiconductor layer 31a is formed in an arc shape along a circle centered on the center position of the conductive member 20 (via wiring line). In the XY cross-section, a side surface portion on the other side in the X direction of the semiconductor layer 31a is formed linearly along the conductive layer 72, for example. In the XY cross-section, in the insulating layer 41a, a portion provided in the vicinity of the boundary between the read transistor RT and the read word line RWL is in contact with two insulating members 11 adjacent in the Y direction. Although not illustrated, in the XY cross-section, a side surface portion on the other side in the X direction of the conductive layer 50 is formed in an arc shape along a circle centered on the center position of the conductive member 20 (via wiring line). Although not illustrated, in the XY cross-section, a side surface portion on one side in the X direction of the conductive layer 51 is formed in an arc shape along a circle centered on the center position of the conductive member 20 (via wiring line).

As illustrated in FIG. 69, in the XY cross-section, side surface portions on both sides in the Y direction of the conductive layer 60 are formed linearly along the two insulating members 11 adjacent in the Y direction. In addition, in the XY cross-section, each of the side surface portion on one side in the X direction of the conductive layer 60 and the side surface portion on the other side in the X direction of the conductive layer 60 is formed in an arc shape along a circle centered on the center position of the conductive member 21 (via wiring line). In the XY cross-section, the insulating layer 61 is provided so as to surround the outer periphery of the conductive layer 60. Specifically, in the XY cross-section, the insulating layer 61 has a portion sandwiched between the insulating member 11 on one side in the Y direction and the conductive layer 60 and a portion sandwiched between the insulating member 11 on the other side in the Y direction and the conductive layer 60.

As described above, in two adjacent memory cells MCa in the Z direction, two adjacent conductive layers 51 (storage nodes SN) in the Z direction are adjacent with the conductive layer 60 interposed therebetween as in the first embodiment. The conductive layer 60 is provided so as to overlap the conductive layer 51 (storage node SN) in plan view. It is preferable that the conductive layer 60 completely overlap the conductive layer 51 in plan view. Then, the conductive layer 60 is electrically connected to the conductive member 21. Accordingly, the conductive layer 60 can function as a shield electrode SH.

Other configurations of the memory device 100A according to the fourth embodiment are similar to those of the memory device 100 according to the first embodiment.

### <4-2> Manufacturing Method

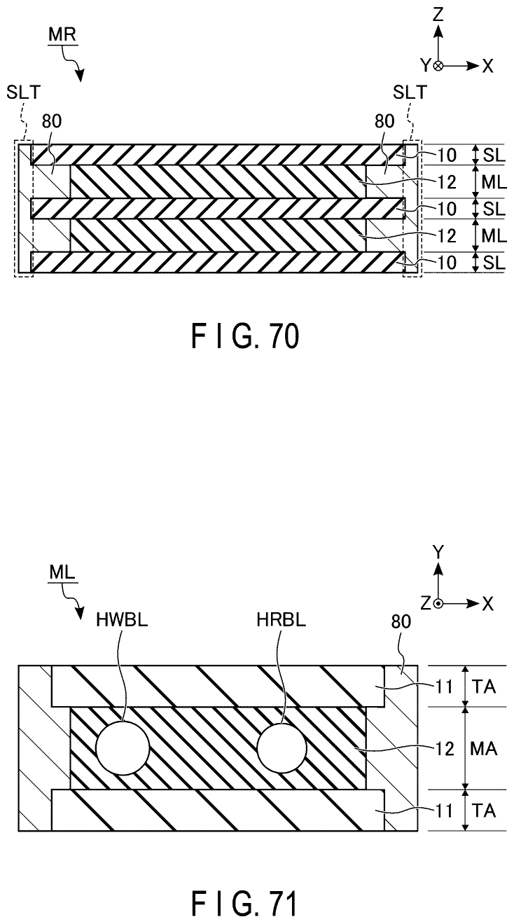

Next, as a method for manufacturing the memory device 100A according to the fourth embodiment, a process of forming the memory cell array 110 will be described with reference to FIGS. 70 to 79. Each of FIGS. 70 to 79 illustrates the same region as any one of the memory region MR illustrated in FIG. 67, the memory layer ML illustrated in FIG. 68, or the separation layer SL illustrated in FIG. 69. Each of FIGS. 70 to 79 is a cross-sectional view illustrating an example of a structure in a step for manufacturing the memory device 100A according to the fourth embodiment.

In the method for manufacturing the memory device 100A according to the fourth embodiment, first, the same processing as the processing described with reference to FIGS. 7 to 10 in the first embodiment is executed. Accordingly, a structure illustrated in FIG. 70 is formed.

Next, as illustrated in FIG. 71, in the memory area MA, a hole HWBL is formed in a portion corresponding to the write bit line WBL, and a hole HRBL is formed in a portion corresponding to the read bit line RBL. Although not illustrated, each of the holes HWBL and HRBL is formed, by anisotropic etching processing such as RIE, so as to penetrate the insulating layers 10 and the sacrificial members 12 that extend in the Z direction and are stacked.

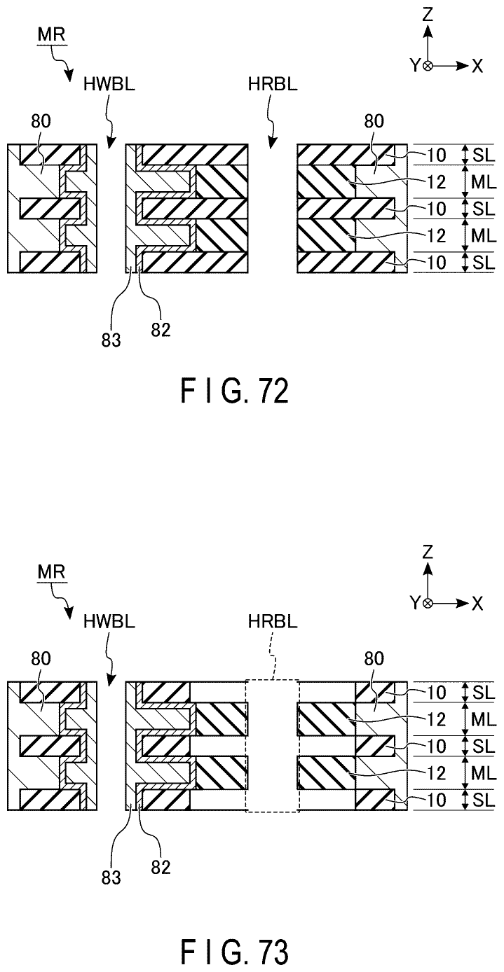

Next, as illustrated in FIG. 72, (1) recessed portions are formed by selectively removing the sacrificial member 12 of each memory layer ML through the hole HWBL, and (2) the conductive film 82 and the sacrificial member 83 are sequentially formed so as to fill the formed recessed portions. In the present step, for example, wet etching processing is used to form the recessed portion. The recessed portion formed corresponding to the hole HWBL corresponds to a place where the write transistor WT is formed. The conductive film 82 of the hole HWBL is in contact with each of the sacrificial members 12 and 80 in the memory layer ML. In addition, the conductive film 82 covers the upper surface, the lower surface, both side surfaces in the X direction, and both side surfaces in the Y direction of the insulating layer 10 in the hole HWBL. In the present step, the sacrificial member 83 may be formed so as to embed the hole HGND. Each of the conductive film 82 and the sacrificial member 83 is formed by, for example, CVD or the like. The conductive film 82 is, for example, titanium nitride (TiN). The sacrificial member 83 is, for example, amorphous silicon (aSi).

Next, as illustrated in FIG. 73, a part of the insulating layer 10 is selectively removed through the hole HRBL. In the present step, for example, wet etching processing is used to remove the insulating layer 10. In the present step, the recessed portion that is in contact with the hole HRBL and formed in the separation layer SL corresponds to a place where the shield electrode SH is formed.

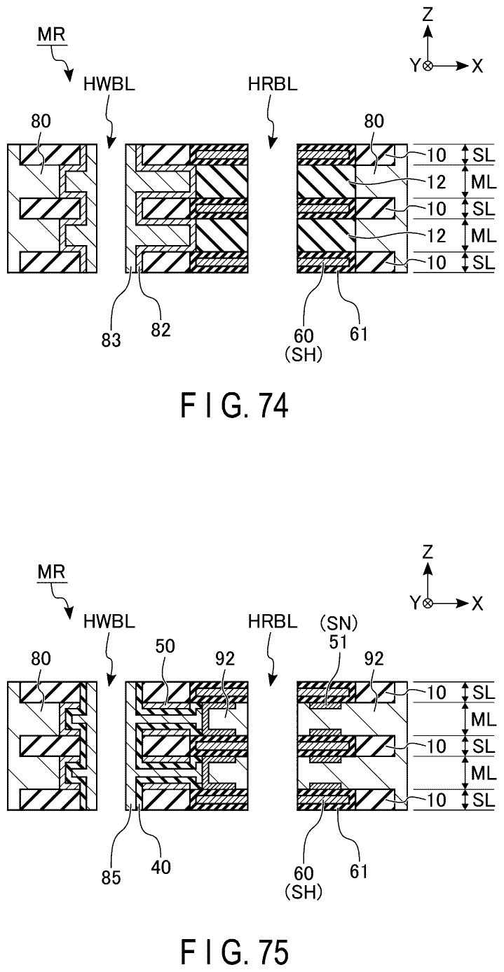

Next, as illustrated in FIG. 74, (1) an insulating film corresponding to the insulating layer 61 and a conductive film corresponding to the conductive layer 60 are formed, and (2) the insulating film and the conductive film provided on the side surface portion of the hole HRBL are removed. Accordingly, a structure corresponding to the shield electrode SH is formed. In addition, by the present step, the side surface of the sacrificial member 12 of each memory layer ML is exposed in the hole HRBL. In the present step, for example, CVD is used to form the insulating film and the conductive film.

Next, as illustrated in FIG. 75, the sacrificial member 12 of each memory layer ML is selectively removed through the hole HRBL, and in each memory layer ML, conductive layers 50 and 51 are formed, an insulating layer 40 is formed, and sacrificial members 85 and 92 are formed. The structure illustrated in FIG. 75 can be formed by appropriately executing etching processing and film formation processing using the holes HWBL and HRBL and the slit SLT on the other side in the X direction. The conductive layer 50 of each memory layer ML is formed by processing the conductive film 82. The conductive layer 51 is, for example, a conductive oxide such as indium tin oxide (ITO). The sacrificial member 85 is provided so as to cover the insulating layer 40 at least in the hole HWBL. The sacrificial member 92 is provided in each memory layer ML so that a space sandwiched by the conductive layers 51 formed in a disk shape and a space in which the read word line RWL is formed are filled. Each of the sacrificial members 85 and 92 is, for example, amorphous silicon (aSi).

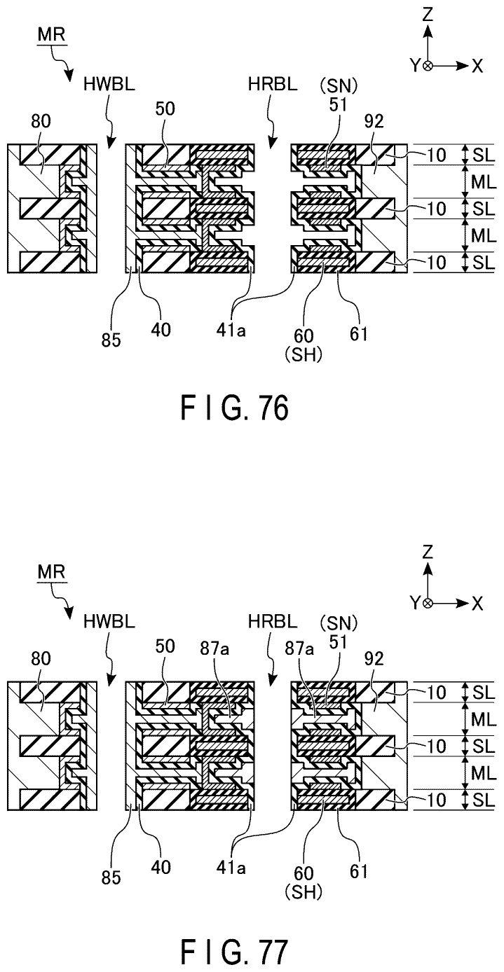

Next, as illustrated in FIG. 76, (1) a part of the sacrificial member 92 provided in the memory layer ML is selectively removed through the hole HRBL, and (2) an insulating layer 41a is formed through the hole HRBL. The conductive layer 51 processed in the present step corresponds to the shape of the conductive layer 51 (storage node SN) illustrated in FIG. 67. For example, wet etching processing is used to remove the sacrificial member 92. The insulating layer 41 is formed as a film by, for example, CVD or the like.

Next, as illustrated in FIG. 77, in each memory layer ML, a sacrificial member 87 is embedded in a space sandwiched in the Z direction by the insulating layers 41. The sacrificial member 87 is formed as a film by, for example, CVD or the like. In the present step, the sacrificial members 87 formed on the side surface portions of the hole HRBL are removed by etch back processing. The sacrificial member 87 is, for example, amorphous silicon (aSi).

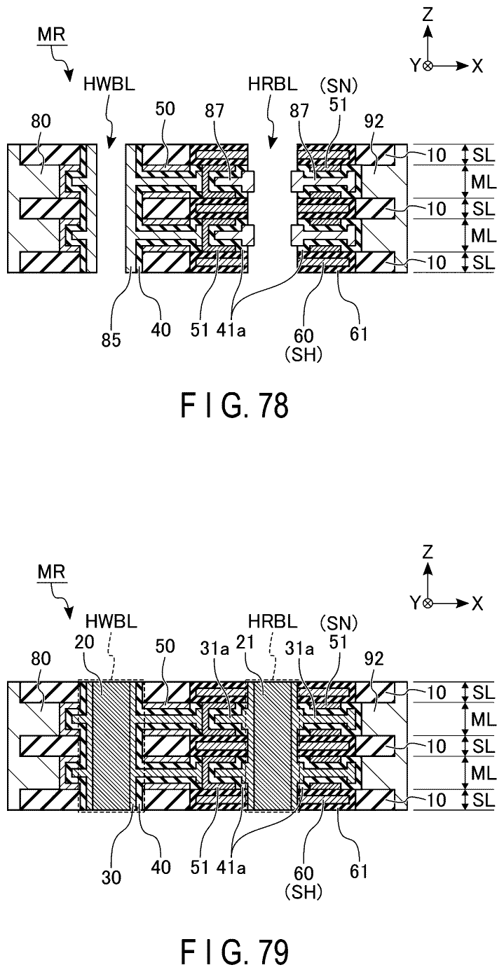

Next, as illustrated in FIG. 78, the insulating layer 41a formed on the side surface portion of the hole HRBL in each separation layer SL is selectively removed through the hole HRBL. Accordingly, a part of the conductive layer 60 is exposed in a portion corresponding to each separation layer SL in the hole HRBL. For example, wet etching processing is used to remove the insulating layer 41a.

Next, as illustrated in FIG. 79, (1) the sacrificial members 85 and 87 are selectively removed, (2) semiconductor layers 30 and 31a are formed, and (3) conductive members 20 and 21 are respectively embedded in the holes HWBL and HRBL. Thereafter, the sacrificial member 80 and a part of the insulating layer 41a on the read bit line RBL side are removed, and a configuration corresponding to the write word line WWL and the read word line RWL is formed. As a result, the structure of the memory cell array 110 illustrated in FIGS. 67 to 69 is completed.

### <4-3> Advantageous Effects of Fourth Embodiment

The memory device 100A according to the fourth embodiment has a configuration in which a memory cell MC having a 2 transistor 0 capacitor (2T0C) configuration and the shield electrode SH described in the first embodiment are combined. The shield electrode SH of the fourth embodiment can suppress interference between two memory cells MCa arranged above and below the shield electrode SH.

As a result, as in the first embodiment, the memory device 100A according to the fourth embodiment can reduce the pitch of the memory cells MCa arranged in the Z direction, and can provide a high-density and low-cost three-dimensional stacked memory. Furthermore, as in the first embodiment, since the shield electrode SH of the fourth embodiment can add capacitance (<1 fF) between the storage node SN and the conductive member 21, the shield electrode SH can improve noise resistance.

### <5> OTHERS

The memory device 100 according to the above embodiments has a configuration in which a plurality of memory cells MC each including at least two transistors formed in the horizontal direction (X direction) are stacked in the vertical direction (Z direction) of the semiconductor substrate SUA. Each of the write transistor WT and the read transistor RT is formed in a disk-shaped GAA structure. The shield electrode SH is disposed between two storage nodes SN adjacent in the Z direction. The shield electrode SH is connected to an electrode in a vertical hole (hole HGND or HRBL).

In the above embodiments, names described as “GND” such as the ground line GND and the hole HGND are used for the vertical wiring line arranged at the center of the memory cell MC, but these wiring lines are not necessarily grounded. In the above embodiments, the ground line GND may be paraphrased as a “power line PL”, a “center line”, or the like. Similarly, the hole HGND may be paraphrased as a “hole HPL”, a “hole HCL”, or the like.

It should be noted that in the present specification, a direction intersecting a predetermined surface may be referred to as a “first direction”, a direction intersecting the first direction along the predetermined surface may be referred to as a “second direction”, and a direction intersecting the second direction along the predetermined surface may be referred to as a “third direction”. Each of the first direction, the second direction, and the third direction may or may not correspond to any one of the X direction, the Y direction, or the Z direction. The gate electrode may be referred to as a “gate”. One end electrode may be referred to as “one end”. The other end electrode may be referred to as “the other end”. The manufacturing method described in the above embodiments is merely an example. Other manufacturing methods may be used as long as the structure described in each of the embodiments can be formed.

In the present specification, “connection” indicates electrically connected, and for example, does not exclude another element being interposed in between. “Electrically connected” may be with an insulator interposed in between as long as it can operate in the same manner as electrically connected. The write word line WWL, the read word line RWL, the write bit line WBL, the read bit line RBL, or the like may be referred to as a “wiring line”. The conductive layer may be referred to as a “conductive film”. The insulating layer may be referred to as an “insulating film”.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein 10 may be made without departing from the spirit of the inventions. The accompanying claims and their equivalents are intended to cover such forms or modification as would fall within the scope and spirit of the inventions.

What is claimed is:

1. A memory device comprising:
a substrate;
a first conductive member and a second conductive member, each of the first conductive member and the second conductive member provided to extend in a first direction intersecting a surface of the substrate, the first conductive member and the second conductive member being arranged in a second direction parallel to the surface of the substrate;
a plurality of memory cells arranged in the first direction, each of the memory cells including a first transistor and a second transistor arranged in the second direction, the first transistor including a gate electrode and a channel region electrically connected to the first conductive member, the second transistor including a channel region electrically connected to the second conductive member and a gate electrode electrically connected to the channel region of the first transistor; and
a shield electrode electrically connected to the second conductive member between two memory cells adjacent in the first direction among the memory cells, the shield electrode provided to overlap the gate electrode of the second transistor in the first direction.

2. The memory device according to claim 1,
wherein the channel region of the first transistor covers a periphery of the first conductive member as viewed from the first direction,
wherein the channel region of the second transistor covers a periphery of the second conductive member as viewed from the first direction, and
wherein the shield electrode covers a periphery of the second conductive member as viewed from the first direction.

3. The memory device according to claim 2,
wherein the first transistor includes a first semiconductor layer that functions as the channel region of the first transistor, a first insulating layer that covers an upper surface, a lower surface, and one side in the second direction of the first semiconductor layer, and a first conductive layer that covers an upper surface, a lower surface, and one side in the second direction of the first insulating layer and functions as the gate electrode of the first transistor, and
wherein the second transistor includes a second semiconductor layer that functions as the channel region of the second transistor, a second insulating layer that covers an upper surface, a lower surface, and one side in the second direction of the second semiconductor layer, and a second conductive layer that covers an upper surface, a lower surface, and one side in the second direction of the second insulating layer, is connected to the first semiconductor layer, and functions as the gate electrode of the second transistor.

4. The memory device according to claim 3, wherein the second conductive layer is used as a storage node of the memory cell.

5. The memory device according to claim 3, wherein as viewed from the first direction, the shield electrode is larger than the second conductive layer and overlaps the entire second conductive layer.

6. The memory device according to claim 3, further comprising an insulating film configured to separate and insulate between the shield electrode and the second conductive layer, the insulating film having a composition different from a composition of each of the first insulating layer and the second insulating layer.

7. The memory device according to claim 6,
wherein each of the first insulating layer and the second insulating layer contains silicon oxide, and
wherein the insulating film contains any one of silicon nitride, silicon oxynitride, hafnium oxide, or aluminum oxide.

8. The memory device according to claim 3, wherein each of the first semiconductor layer and the second semiconductor layer contains an oxide semiconductor.

9. The memory device according to claim 8, wherein the oxide semiconductor contains at least one element of gallium and aluminum, as well as indium, zinc, and oxygen.

10. The memory device according to claim 1, wherein the shield electrode contains a conductive oxide.

11. The memory device according to claim 10, wherein the conductive oxide contains indium tin oxide.

12. The memory device according to claim 1,
further comprising:
a third conductive member extending in the first direction and provided on another side in the second direction with respect to the second conductive member,
a first word line provided for each of the memory cells and electrically connected to the gate electrode of the first transistor, and
a second word line provided for each of the memory cells,
wherein each of the memory cells further includes a third transistor provided on another side in the second direction with respect to the second transistor, and
wherein the third transistor includes a channel region electrically connected to the third conductive member and electrically connected to the channel region of the second transistor and a gate electrode electrically connected to the second word line.

13. The memory device according to claim 2,
further comprising:
a third conductive member extending in the first direction and provided on another side in the second direction with respect to the second conductive member,
a first word line provided for each of the memory cells and electrically connected to the gate electrode of the first transistor, and
a second word line provided for each of the memory cells,
wherein each of the memory cells further includes a third transistor provided on another side in the second direction with respect to the second transistor, and
wherein the third transistor includes a channel region that covers a periphery of the third conductive member as viewed from the first direction, is electrically connected to the third conductive member, and is electrically connected to the channel region of the second transistor, and a gate electrode electrically connected to the second word line.

14. The memory device according to claim 13,
wherein the first transistor includes:
a first semiconductor layer that functions as the channel region of the first transistor,
a first insulating layer that covers an upper surface, a lower surface, and one side in the second direction of the first semiconductor layer, and
a first conductive layer that covers an upper surface, a lower surface, and one side in the second direction of the first insulating layer and functions as the gate electrode of the first transistor,
wherein the second transistor includes:
a second semiconductor layer that functions as the channel region of the second transistor,
a second insulating layer that covers an upper surface, a lower surface, and one side in the second direction of the second semiconductor layer, and
a second conductive layer that covers an upper surface, a lower surface, and one side in the second direction of the second insulating layer, is connected to the first semiconductor layer, and functions as the gate electrode of the second transistor, and
wherein the third transistor includes:
a third semiconductor layer that functions as the channel region of the third transistor,
a third insulating layer that covers an upper surface, a lower surface, and another side in the second direction of the third semiconductor layer, and
a third conductive layer that covers an upper surface, a lower surface, and another side in the second direction of the third insulating layer, is electrically connected to the second word line, and functions as the gate electrode of the third transistor.

15. The memory device according to claim 14, wherein an end portion on another side in the second direction of the first conductive layer and an end portion on one side in the second direction of the second conductive layer face each other, with a distance.

16. The memory device according to claim 14, wherein as viewed from the first direction, each of the shield electrode and the second conductive layer has a portion provided in an arc shape along a circle centered on a center position of the second conductive member on one side in the second direction, and has a portion provided in an arc shape along a circle centered on a center position of the second conductive member on another side in the second direction.

17. The memory device according to claim 14, wherein as viewed from the first direction, each of the shield electrode and the second conductive layer has a portion provided in an arc shape along a circle centered on a center position of the first conductive member on one side in the second direction, and has a portion provided in an arc shape along a circle centered on a center position of the third conductive member on another side in the second direction.

18. The memory device according to claim 14, wherein as viewed from the first direction, the shield electrode has a portion provided in an arc shape along a circle centered on a center position of the first conductive member on one side in the second direction, or has a portion provided in an arc shape along a circle centered on a center position of the third conductive member on another side in the second direction.

19. The memory device according to claim 18,
wherein in a case where the shield electrode has a portion provided in an arc shape along a circle centered on a center position of the first conductive member on one side in the second direction as viewed from the first direction,
the shield electrode further includes a portion provided in an arc shape along a circle centered on a center position of the second conductive member on another side in the second direction as viewed from the first direction, and
the second conductive layer has a portion provided in an arc shape along a circle centered on a center position of the first conductive member on one side in the second direction and a portion provided in an arc shape along a circle centered on a center position of the second conductive member on another side in the second direction as viewed from the first direction, and
wherein in a case where the shield electrode has a portion provided in an arc shape along a circle centered on a center position of the third conductive member on another side in the second direction as viewed from the first direction,
the shield electrode further includes a portion provided in an arc shape along a circle centered on a center position of the second conductive member on one side in the second direction as viewed from the first direction, and
the second conductive layer has a portion provided in an arc shape along a circle centered on a center position of the third conductive member on another side in the second direction and a portion provided in an arc shape along a circle centered on a center position of the second conductive member on one side in the second direction as viewed from the first direction.

20. The memory device according to claim 15, wherein an interval between an upper end and a lower end in the first direction of the second conductive layer is narrower than each of an interval between an upper end and a lower end in the first direction of the first conductive layer and an interval between an upper end and a lower end in the first direction of the third conductive layer.

21. The memory device according to claim 14, wherein each of the first conductive layer and the third conductive layer does not have a portion that overlaps the shield electrode in the first direction.

22. The memory device according to claim 1, further comprising:
a first word line provided for each of the memory cells and electrically connected to the gate electrode of the first transistor, and
a second word line provided for each of the memory cells and electrically connected to the channel region of the second transistor.

23. The memory device according to claim 22,
wherein the channel region of the first transistor covers a periphery of the first conductive member as viewed from the first direction,
wherein the channel region of the second transistor covers a periphery of the second conductive member as viewed from the first direction, and
wherein the shield electrode covers a periphery of the second conductive member as viewed from the first direction.

24. The memory device according to claim 23,
wherein the first transistor includes a first semiconductor layer that functions as the channel region of the first transistor, a first insulating layer that covers an upper surface, a lower surface, and one side in the second direction of the first semiconductor layer, and a first conductive layer that covers an upper surface, a lower surface, and one side in the second direction of the first insulating layer and functions as the gate electrode of the first transistor, and
wherein the second transistor includes a second semiconductor layer that functions as the channel region of the second transistor, a second insulating layer that covers an upper surface, a lower surface, and one side in the second direction of the second semiconductor layer, and a second conductive layer that covers an upper surface, a lower surface, and one side in the second direction of the second insulating layer, is connected to the first semiconductor layer, and functions as the gate electrode of the second transistor.

25. The memory device according to claim 24,
wherein the shield electrode has a portion provided in an arc shape along a circle centered on a center position of the second conductive member on each of one side and another side in the second direction as viewed from the first direction, and
wherein the first conductive layer has a portion provided in an arc shape along a circle centered on a center position of the first conductive member on another side in the second direction as viewed from the first direction.
